(19) United States
(12) Patent Application Publication
(10) Pub. No.: US 2016/0104413 A1
(43) Pub. Date: Apr. 14, 2016

(54) PIXEL ARRAY, ELECTRO OPTICAL DEVICE, ELECTRIC APPARATUS AND PIXEL RENDERING METHOD

(71) Applicant: NLT Technologies, Ltd., Kawasaki (JP)

(72) Inventors: Yojiro MATSUEDA, Kawasaki (JP); Kenichi TAKATORI, Kawasaki (JP); Yoshihiro NONAKA, Kawasaki (JP)

(73) Assignee: NLT Technologies, Ltd., Kawasaki (JP)

(21) Appl. No.: 14/878,013

(22) Filed: Oct. 8, 2015

(30) Foreign Application Priority Data
Oct. 9, 2014 (JP) 2014-207786

(51) Int. Cl. G09G 3/20; H01L 27/32; G09G 3/32

(52) U.S. Cl. CPC G09G 3/2074; G09G 3/3208; H01L 27/3218; G09G 2300/0452; G09G 2320/0666

(57) ABSTRACT

Provided is a pixel array having a pixel arrangement structure in which a subpixel of the first color having the highest luminosity factor, a subpixel of the second color and a subpixel of the third color having the lowest luminosity factor are arranged in matrix, a row including the subpixel of the first color and the subpixel of the second color that are alternately arranged and a row including the subpixel of the first color and the subpixel of the third color that are alternately arranged are alternately arranged, and a column including the subpixel of the first color and the subpixel of the second color that are alternately arranged and a column including the subpixel of the first color and the subpixel of the third color that are alternately arranged are alternately arranged. The row including the subpixels of the first color and the third color is higher than the row including the subpixels of the first color and the second color, and the subpixel of the first color in the row including the subpixels of the first color and the second color has an area of a light-emitting region substantially equal to that in the subpixel of the first color in the row including the subpixels of the first color and the third color.

### CROSS-REFERENCE TO RELATED APPLICATION

This non-provisional application claims priority under 35 U.S.C. §119(a) on Patent Application No. 2014-207786 filed in Japan on Oct. 9, 2014, the entire contents of which are hereby incorporated by reference.

### FIELD

The present invention relates to a pixel array, an electro optical device, an electric apparatus and a pixel rendering method, and more particularly to a pixel array with a staggered arrangement structure, an electro optical device including the pixel array, an electric apparatus utilizing the electro optical device as a display device, and a pixel rendering method.

### BACKGROUND

Since an organic Electro Luminescence (EL) element is a self-light-emitting element of a current driven type, the need for a backlight is eliminated while the advantage of low power consumption, high viewing angle, high contrast ratio or the like is obtained; it is expected to perform well in the development of a flat panel display.

In an organic EL display device using such an organic EL element, subpixels of different colors of red (R), green (G) and blue (B) are used to constitute a large number of pixels, which makes it possible to display various kinds of color images. While these subpixels of R, G, and B (RGB) may be located in various different forms, they are generally arranged in stripes by equally placing subpixels of different colors (so-called RGB vertical stripe arrangement), as illustrated in FIG. 1. All colors can be displayed by adjusting the brightness among the three subpixels. In general, adjacent three subpixels of R, G and B are collectively regarded as one rectangular pixel, and such rectangular pixels are arranged in a square to realize a dot matrix display. In the display device of a dot matrix type, image data to be displayed has a matrix arrangement of n×m. A correct image can be displayed by associating the image data with each pixel one for one.

Furthermore, organic EL devices have different structures including a color filter type which creates the three colors of RGB with a color filter on the basis of a white organic EL element, and a side-by-side selective deposition type which deposits different colors on the respective organic EL materials for the three colors of RGB. While the color filter type has a disadvantage in that the light use efficiency is lowered as the color filter absorbs light, resulting in higher power consumption, the side-by-side selective deposition type can easily have wider color gamut due to its high color purity and can have higher light use efficiency because a color filter is eliminated, thereby being widely used.

In the side-by-side selective deposition type, Fine Metal Mask (FMM) is used in order to individually color organic EL materials. It is, however, difficult to fabricate FMM because pitches thereof are made finer to be adapted for recent highly-refined organic EL display devices. To address such a problem, using the characteristics of human color vision, i.e. human eye being insensitive to R and B whereas sensitive to G, a pixel arrangement structure in which subpixels are constituted with two colors of G and B, or G and R, and a color expression requiring a subpixel of a missing color compared to the RGB arrangement is reproduced into a pseudo array by combining the two-color subpixels with an adjacent pixel having a subpixel of the missing color (so-called PenTile (registered trademark) arrangement) has been proposed (U.S. Pat. No. 6,771,028, US Patent Application Publication No. 2002/0186214, US Patent Application Publication No. 2004/0113875 and US Patent Application Publication No. 2004/0201558, for example).

### SUMMARY

Since organic EL materials have different lifetime (aging speed) for colors of RGB and the organic EL material for B has the shortest lifetime, the colors lose balance over time, which shortens the lifetime of the display device. To address this problem, increasing the size of a subpixel of B may be conceivable in order to ensure a longer lifetime.

In the PenTile arrangement, however, the subpixels of G are arranged in a line, which requires an FMM to have a constant slit width when the subpixels of G are fabricated with the FMM. It is thus difficult to increase the size of a subpixel of B (i.e., to decrease the size of a subpixel of G) in a pixel constituted by the subpixels of G and B. Moreover, even if the size of a subpixel of B is increased while the size of a subpixel of G is decreased in the pixel constituted by the subpixels of G and B, the areas of the vertical adjacent subpixels of G to the subpixel G are changed, which causes a change in the area center of their subpixels of G. If the area center of subpixels of G is changed, the distribution of luminosity factors of RGB together will be the highest at a displaced position from the center of a pixel, increasing bias in luminosity factors in the pixel. Although such bias in the luminosity factors is not viewed at the inner side of an image, it becomes more obvious when the edge of the image extends along the alignment direction of a pixel, which causes such a phenomenon that the edge of the image appears to be colored (so-called color edge), significantly degrading the display quality.

It is thus necessary to increase the size of a subpixel of B in order to extend the lifetime of a display device, while the increase in the size of a subpixel of B in the PenTile arrangement also increases the bias in luminosity factors within a pixel. Hence, the PenTile arrangement has a problem in that extension of the lifetime of a display device and prevention of bias in luminosity factors cannot be realized at the same time.

Furthermore, in the display which arranges pixels constituted by subpixels of RGB, error diffusion processing is performed to prevent coloring at an edge of a displayed image. While, in the PenTile arrangement, the subpixels of G are continuously arranged in the vertical direction and not a subpixel of G in the vertical direction of the subpixel of R or B, which makes the error diffusion processing insufficient in the case where the subpixel of R or B is located at the edge of an image. This results in a problem of degrading in the display quality due to occurrence of coloring.

One aspect of the present invention is directed to a pixel array having a pixel arrangement structure in which a subpixel of a first color having a highest luminosity factor, a subpixel of a second color and a subpixel of a third color having a lowest luminosity factor are arranged in matrix, a row including alternative arrangement of the subpixels of the first color and the second color (the first and second colors row) and a row including alternative arrangement of the subpixels of the first color and the third color (the first and third colors row) are alternately arranged, and a column including alternative arrangement of the subpixels of the first color and the second color (the first and second colors column) and a column including alternative arrangement of the subpixels of the first color and the third color (the first and third colors column) are alternately arranged.

The first and third colors row is higher than the first and second colors row.

The subpixel of the first color in the first and second colors row has an area of a light-emitting region substantially equal to an area of it in the subpixel of the first color in the first and third colors row.

According to one aspect of the present invention, an electro optical device includes the pixel array described above, and a circuit part driving the pixel array.

According to one aspect of the present invention, an electric apparatus includes, as a display device, an organic electroluminescence device in which the pixel array described above, defined by an aperture of a metal mask used when organic electroluminescence material is deposited to the light-emitting region of a subpixel, and a circuit part driving the pixel array are formed on a substrate.

One aspect of the present invention is directed to a pixel rendering method in a pixel array having a pixel arrangement structure in which a subpixel of a first color having a highest luminosity factor, a subpixel of a second color and a subpixel of a third color having a lowest luminosity factor are arranged in matrix, a row including alternative arrangement of the subpixels of the first color and the second color and a row including alternative arrangement of the subpixels of the first color and the third color are alternately arranged, and a column including alternative arrangement of the subpixels of the first color and the second color and a column including alternative arrangement of the subpixels of the first color and the third color are alternately arranged.

An image displayed in the pixel array has data of the first color, the second color and the third color for respective subpixels. Based on the data of the first color of the image in a predetermined subpixel located at a singularity of the image displayed in the pixel array, luminance of a subpixel adjacent to the predetermined subpixel is set.

It is to be understood that both the foregoing general description and the following detailed description are exemplary and explanatory and are not restrictive of the invention.

### BRIEF DESCRIPTION OF THE DRAWINGS

FIG. 1 is a plan view schematically illustrating a pixel arrangement structure (RGB vertical stripe arrangement) of the conventional organic EL display device;

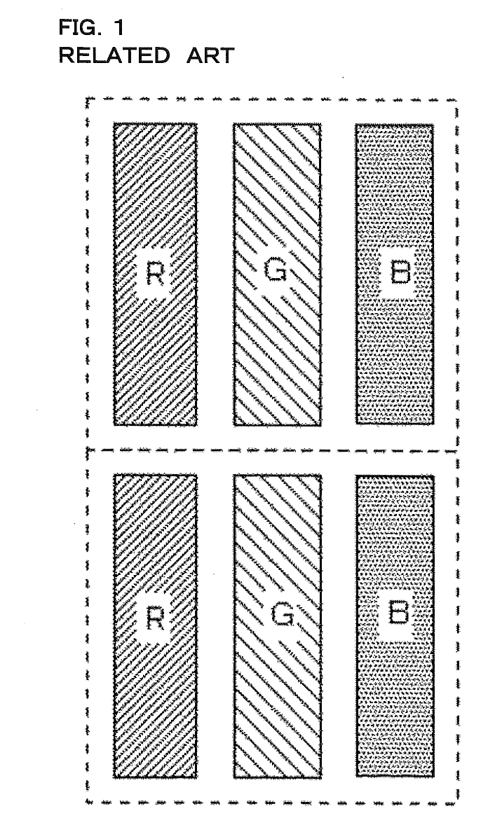

FIG. 2 is a plan view schematically illustrating a pixel arrangement structure (PenTile arrangement) of the conventional organic EL display device;

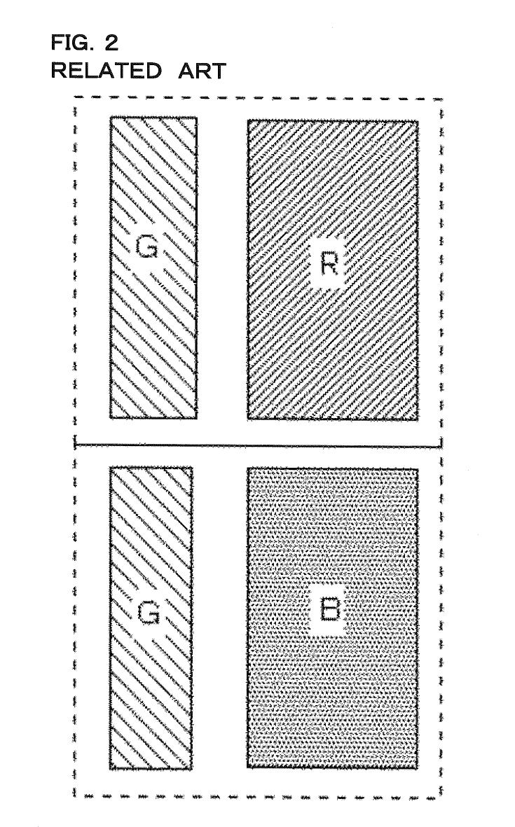

FIG. 3 is a plan view illustrating an organic EL display device according to an embodiment;

FIG. 4 is a plan view schematically illustrating a configuration of a pair of pixels (corresponding to four subpixels) in an organic EL display device according to an embodiment;

FIG. 5 is a section view schematically illustrating a configuration of a pixel (corresponding to one subpixel) in an organic EL display device according to an embodiment;

FIG. 6 is a main circuit configuration diagram of a pixel in an organic EL display device according to an embodiment;

FIG. 7 is a waveform illustration of a pixel in an organic EL display device according to an embodiment;

FIG. 8 is an output characteristic diagram of a drive TFT in an organic EL display device according to an embodiment;

FIG. 9 is an arrangement diagram of wirings and elements according to an embodiment (independent power source);

FIG. 10 is an arrangement diagram of wirings and elements according to an embodiment (common power source);

FIG. 11 is a plan view illustrating a pixel arrangement structure according to an embodiment;

FIG. 12 is a plan view illustrating another example of a pixel arrangement structure according to an embodiment;

FIG. 13 is a plan view illustrating another example of a pixel arrangement structure according to an embodiment;

FIG. 14 is a plan view illustrating another example of a pixel arrangement structure according to an embodiment;

FIG. 15 is a plan view illustrating one example of rendering in a pixel arrangement structure according to an embodiment (in case of a high resolution image);

FIG. 16 is a plan view illustrating one example of rendering in a pixel arrangement structure according to an embodiment (in case where a corner portion in data display is R or B);

FIG. 17 is a plan view illustrating one example of rendering in a pixel arrangement structure according to an embodiment (in case where a rectilinear boundary portion in data display is R or B);

FIG. 18 is a plan view illustrating one example of rendering in a pixel arrangement structure according to an embodiment (in case of point display of G in data display);

FIG. 19 is a plan view illustrating one example of rendering in a pixel arrangement structure according to an embodiment (in case of point display of R, B in data display);

FIG. 20 is a plan view illustrating one example of rendering in a pixel arrangement structure according to an embodiment (in case of point display of R, B in data display);

FIG. 21 is a plan view illustrating one example of rendering in a pixel arrangement structure according to an embodiment (in case of point display of R, B in data display);

FIG. 22 is a diagram for explaining detection method of a singularity such as a corner, a boundary or a point in displayed image;

FIG. 23 is a diagram for explaining rearrangement (conversion of resolution) of image data according to an embodiment;

FIG. 24 is a plan view illustrating a manufacturing procedure (first step) of an organic EL display device according to the first example;

FIG. 25 is a section view illustrating a manufacturing procedure (first step) of an organic EL display device according to the first example, specially extracting a TFT part, a retention capacitor and a light emitting element illustrated in one subpixel for explanation purpose, corresponding to FIG. 24;

FIG. 26 is a plan view illustrating a manufacturing procedure (second step) of an organic EL display device according to the first example;

FIG. 27 is a section view illustrating a manufacturing procedure (second step) of an organic EL display device according to the first example, specially extracting a TFT part, a retention capacitor and a light emitting element illustrated in one subpixel for explanation purpose, corresponding to FIG. 26;

FIG. 28 is a plan view illustrating a manufacturing procedure (third step) of an organic EL display device according to the first example;

FIG. 29 is a section view illustrating a manufacturing procedure (third step) of an organic EL display device according to the first example, specially extracting a TFT part, a retention capacitor and a light emitting element illustrated in one subpixel for explanation purpose, corresponding to FIG. 28;

FIG. 30 is a plan view illustrating a manufacturing procedure (fourth step) of an organic EL display device according to the first example;

FIG. 31 is a section view illustrating a manufacturing procedure (fourth step) of an organic EL display device according to the first example, specially extracting a TFT part, a retention capacitor and a light emitting element illustrated in one subpixel for explanation purpose, corresponding to FIG. 30;

FIG. 32 is a section view schematically illustrating a method of fabricating a metal mask according to the first example;

FIG. 33 is a section view schematically illustrating a method of fabricating a metal mask according to the first example;

FIG. 34 is a section view schematically illustrating a method of fabricating a metal mask according to the first example;

FIG. 35 is a plan view schematically illustrating a configuration of a metal mask (configuration of an R aperture) according to the first example;

FIG. 36 is a plan view schematically illustrating a configuration of a metal mask (configuration of a G aperture) according to the first example;

FIG. 37 is a plan view schematically illustrating a configuration of a metal mask (configuration of a B aperture) according to the first example;

FIG. 38 is a section view schematically illustrating a method of forming a film of organic EL material using a metal mask according to the first example;

FIG. 39 is a perspective view illustrating a positional relationship between a metal mask main body and a reinforcement member according to the first example;

FIG. 40 is a section view schematically illustrating a method of forming a film of organic EL material using a metal mask according to the first example;

FIG. 41 is a schematic view illustrating an application example of an organic EL display device according to the second example;

FIG. 42 is a schematic view illustrating an application example of an organic EL display device according to the second example;

FIG. 43 is a schematic view illustrating an application example of an organic EL display device according to the second example;

FIG. 44 is a schematic view illustrating an application example of an organic EL display device according to the second example;

FIG. 45 is a section view schematically illustrating a structure of an organic EL display device according to the third example;

FIG. 46 is a schematic view illustrating an application example of an organic EL display device according to the third example;

FIG. 47 is a schematic view illustrating another application example of an organic EL display device according to the third example; and

FIG. 48 is a schematic view illustrating another application example of an organic EL display device according to the third example.

### DETAILED DESCRIPTION

As described in the background section, an organic EL display device utilizes a pixel arrangement structure of PenTile arrangement in place of RGB vertical stripe arrangement.

Here, organic EL materials for RGB colors have different periods of lifetime (aging speed), the organic EL material for the color B having the shortest lifetime. More specifically, the luminescent color of B has a larger band gap compared to the other luminescent colors, the molecular structure thereof having a small conjugate system, making a molecule itself vulnerable. In particular, a phosphorescent material has high excited triplet energy, which makes it susceptible to a minute amount of quencher present in the system. Moreover, the host material for holding a luminescence material requires even higher excited triplet energy. As the lifetime of the organic EL material for B is short, the colors lose balance over time, resulting in a shorter lifetime of a display device.

To address this problem, a method of increasing the size of a subpixel of B may be conceived in order to ensure a longer lifetime. In the PenTile arrangement, however, the subpixels of G are arranged in a line and the slit width of FMM for forming the subpixels of G needs to be constant. It is thus difficult to increase the size of a subpixel of B (or to decrease the size of a subpixel of G) in a pixel constituted by subpixels of G and B. Moreover, increasing the size of the subpixel of B reduces the size of the subpixel of G accordingly in the pixel constituted by the subpixels of G and B, which changes the areas for the subpixels of G in vertically adjacent pixels, thereby changing the center of the area of subpixels of G. This results in bias of luminosity factors in the pixel, causing a problem of degraded display quality due to generation of a color edge.

In view of the above, according to an embodiment, the arrangement and shapes of subpixels are so devised that the size of the subpixel of B is increased while the center of the area of a subpixel of G is not changed. For example, in a pixel arrangement structure in which a plurality of subpixels corresponding to RGB are arranged in matrix, a row in which subpixels of G and subpixels of R are alternately arranged (R/G row) and a row in which subpixels of G and subpixels of B are alternately arranged (G/B row) are alternately arranged, while a column in which subpixels of G and subpixels of R are alternately arranged (R/G column) and a column in which subpixels of G and subpixels of B are alternately arranged (G/B column) are alternately arranged (i.e. pixel arrangement structure in which subpixels of G are arranged in a staggered manner), the height of the G/B row is made higher than the R/G row (preferably, the area of the light-emitting region of the subpixels of B in the G/B row is made larger than the sum of the light-emitting regions of the subpixels of G in the G/B row and R/G row) while the width of the light-emitting region of the subpixels of G in the G/B row is made narrower than the subpixels of G in the R/G row so that the area of the light-emitting region of the subpixels of G in the G/B row is substantially equal to the area of the light-emitting region of the subpixels of G in the R/G row.

In the case of the pixel arrangement structure as described above, the subpixels of G are arranged in the direction of a diagonal line. Thus, it is necessary to prepare two power supply lines for supplying electric power to two subpixels of G for a set of vertically adjacent pixels or to route one power supply line within a pixel, which however reduces the area of the light-emitting region due to the increase in the number of power supply lines in the former case and increases the power consumption due to the routing of a power supply line in the latter case. In one embodiment, therefore, the components (e.g., TFT part, wiring and contact) of each subpixel in the G/B row and each subpixel in the R/G row are arranged in a symmetrical layout with respect to the Y-axis, which allows one straight power supply line to supply electric power to two subpixels of G in one set of vertically adjacent pixels. Moreover, the power supply line to the subpixels of R and B are also formed in a straight line while the width of the power supply line to the subpixel of B is made wider so as to enhance the reliability of the organic EL display element.

Furthermore, in order to facilitate the manufacturing of the FMM for realizing the pixel arrangement structure as described above, the corner of the light-emitting region of the subpixel of G may be removed (i.e. so as not to remove the corners of the aperture of the FMM on which the organic EL material of G is deposited) to widen the distance between the light-emitting regions of the subpixel of G, or the corner of the light-emitting region of the subpixel of R is removed (i.e. so as not to remove the corner of the aperture of the FMM on which the organic EL material of R is deposited) to widen the distance to the light-emitting region of the subpixel of B.

Furthermore, in the case where a singularity such as a corner, a boundary or a point of a displayed image corresponds to a subpixel of a prescribed color (particularly the subpixel of R or B), the luminance of the surrounding subpixel of another color (particularly the subpixel of G) is adjusted in accordance with a predetermined method of error diffusion processing, to suppress the coloring generated in the singularity and to enhance the display quality.

The embodiment of the present invention will be described below with reference to the drawings. It is to be noted that an electro optical element means a general electron element which changes the optical state of light by an electric action, and includes, in addition to a self-light-emitting element such as an organic EL element, an electron element such as a liquid-crystal element which changes the polarization state of light to implement gradation display. Furthermore, an electro optical device means a display device utilizing an electro optical element for display. Since an organic EL element is suitable and the use of an organic EL element can obtain a current-driven light emitting element which allows self-light emission when driven with current, an organic EL element is given as an example in the description below.

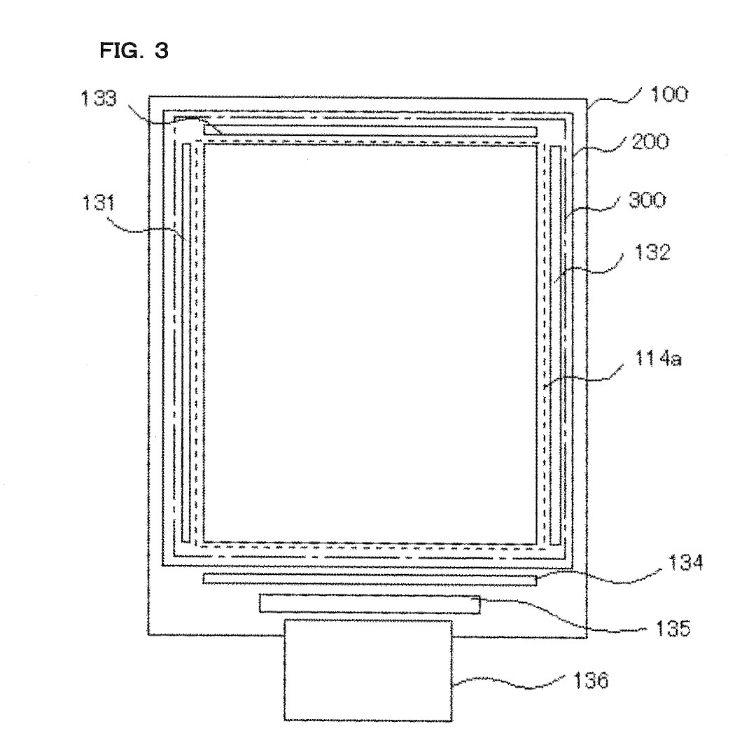

FIG. 3 illustrates an organic EL display device as an example of an electro optical device. The organic EL display device includes, as main components, a thin film transistor (TFT) substrate 100 on which a light emitting element is formed, a sealing glass substrate 200 which seals the light emitting element, and a bonding means (glass frit seal part) 300 which bonds the TFT substrate 100 to the sealing glass substrate 200. Moreover, around a cathode electrode forming region 114a outside the display region of the TFT substrate 100 (active matrix section), for example, a scanning driver 131 (TFT circuit) which drives a scanning line on the TFT substrate 100, an emission control driver 132 (TFT circuit) which controls the light emission period of each pixel, a data line electro static discharge (ESD) protection circuit 133 which prevents damage caused by electrostatic discharge, a demultiplexer (1:n DeMUX 134) which returns a stream at a high transfer rate to multiple streams at a former low transfer rate, a data driver IC 135 which is mounted using an anisotropic conductive film (ACF) and which drives a data line, are located. The organic EL display device is connected with an external device through a flexible printed circuit (FPC) 136. Since FIG. 3 is a mere example of an organic EL device according to the present embodiment, the shape and configuration thereof may appropriately be modified.

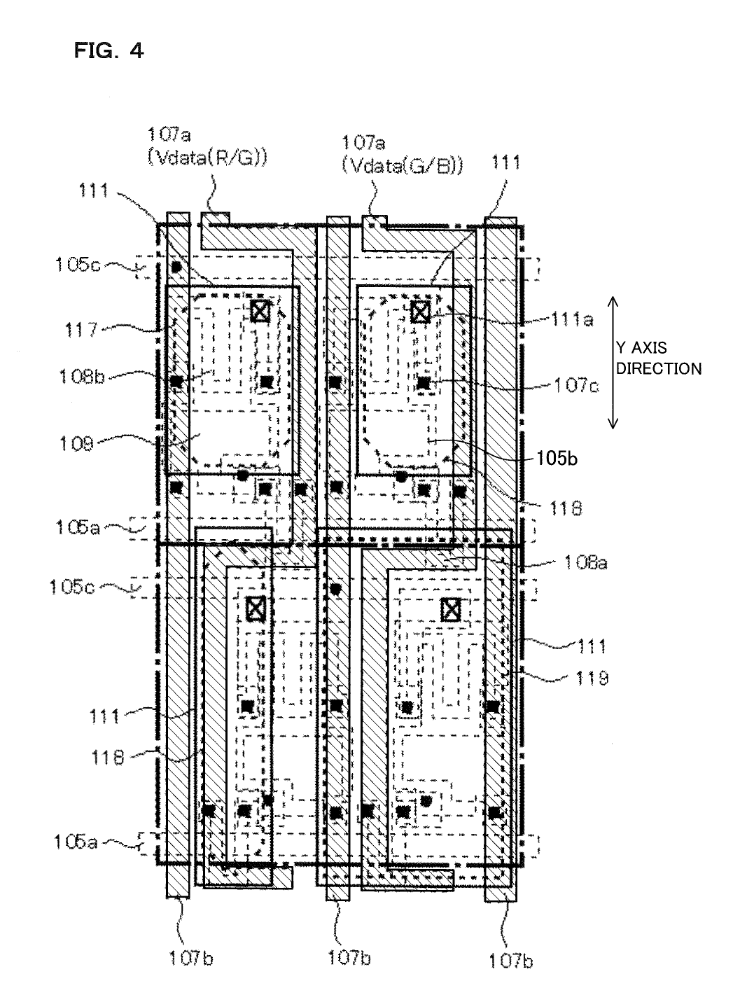

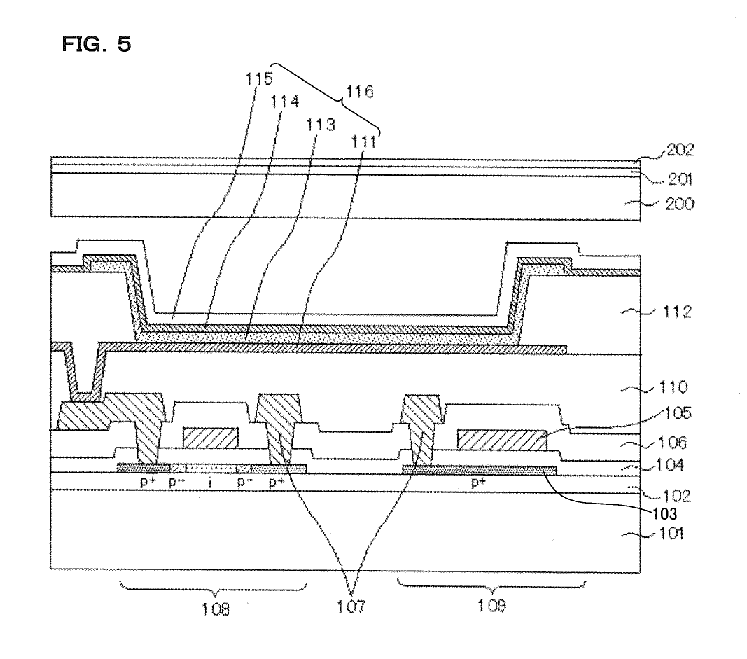

FIG. 4 is a plan view specifically illustrating a pair of pixels (a pixel composed of R/G subpixel at upper side and a pixel composed of G/B subpixel at lower side) in a light emitting element formed on the TFT substrate 100, and the pair of pixels is repeatedly formed in the extending direction of data line and the extending direction of scanning line (gate electrode) (vertical and lateral directions in the drawing). FIG. 5 is a section view specifically illustrating one subpixel. In FIG. 5, for clarifying the structure of a subpixel according to the present embodiment, the regions of a TFT part 108b (M2 drive TFT) and a retention capacitance part 109 in the plan view of FIG. 4 are taken out and simplified for their illustration.

The TFT substrate 100 is constituted by: a poly silicon layer 103 made of low-temperature poly silicon (LTPS) or the like formed on a glass substrate 101 through an underlying insulation film 102; a first metal layer 105 (a gate electrode 105a and a retention capacitance electrode 105b) formed through a gate insulation film 104; a second metal layer 107 (a data line 107a, a power supply line 107b, a source/drain electrode, a first contact part 107c) connected to the poly silicon layer 103 through an aperture formed at an interlayer insulation film 106; and a light emitting element 116 (an anode electrode 111, an organic EL layer 113, a cathode electrode 114 and a cap layer 115) formed through a planarization film 110.

Dry air is enclosed between the light emitting element 116 and the sealing glass substrate 200, which is then sealed by the glass frit seal part 300, to form an organic EL display device. The light emitting element 116 has a top emission structure, in which the light emitting element 116 and the sealing glass substrate 200 are set to have a predetermined space between them while a λ/4 retardation plate 201 and a polarization plate 202 are formed on the side of the light emitting surface of the sealing glass substrate 200, so as to suppress reflection of light entering from the outside.

In FIG. 4, one set of pixels (pixels enclosed by the dashed-dotted line in the drawing) is constituted by a pixel including R/G subpixels adjacent to each other in the horizontal direction and a pixel including G/B subpixels adjacent to each other in the horizontal direction. Each of the subpixels is formed in a region between the data line 107a and the power supply line 107b in the vertical direction and between the gate electrode 105a and the power supply line 105c in the horizontal direction. In or near each region, the switch TFT 108a, the drive TFT 108b and the retention capacitance part 109 are arranged. Here, in the case of the pixel arrangement structure of the RGB vertical stripe arrangement, the data line 107a and the power supply line 107b corresponding to the subpixel of each color extends rectilinearly in the vertical direction, whereas in the case of the staggered arrangement structure of the present embodiment, in order to realize the structure in which the subpixels of G are arranged in diagonal directions, the subpixels in an odd-numbered row and the subpixels in an even-numbered row are arranged in a symmetrical layout with respect to the Y axis while the data line 107a is divided into a data line for R/G subpixel (indicated as Vdata(R/G)) and a data line for G/B subpixel (indicated as Vdata(G/B)) and formed in a bent shape as illustrated, and the power supply line 107b for each color is formed in a straight line.

More specifically, the subpixel of B having the lowest luminosity factor (subpixel at the lower right in FIG. 4) is driven by using the TFT part 108a (M1 switch TFT) and the TFT part 108b (M2 drive TFT) connecting to the gate electrode 105a at the lower side of FIG. 4, the data line 107a for G/B and the power supply line 107b for B. Then, the anode electrode 111 (thick solid line in FIG. 4) for B and the B light-emitting region 119 (thick broken line in FIG. 4) are each formed in a rectangular shape so as to ensure its size as large as possible, the area of the B light-emitting region 119 being formed larger than the sum of the areas of the light-emitting regions of the subpixel of G at the upper right in FIG. 4 and the subpixel of G at the lower left in FIG. 4. Moreover, the power supply line 107b for larger size of B wider than the power supply line 107b for R or G.

Furthermore, the subpixel of R (subpixel at the upper left in FIG. 4) is driven by using the TFT part 108a (M1 switch TFT) and the TFT part 108b (M2 drive TFT) connected to the gate electrode 105a at the central part in FIG. 4, the data line 107a for R/G and the power supply line 107b for R. Furthermore, the anode electrode 111 for R and the R light-emitting region 117 are formed in a size capable of maintaining a distance from the light-emitting regions and the anode electrodes 111 for G and B. If a need arises, four corners of the R light-emitting region 117 may be removed so as to avoid the color mixture with the organic EL layer of R and the organic EL layer of B (to facilitate color dividing with FMM).

Furthermore, the subpixel of G at the upper right in the FIG. 4, among the subpixels of G having the highest luminosity factor, is driven by using the TFT part 108a (M1 switch TFT) and the TFT part 108b (M2 drive TFT) connecting to the gate electrode 105a at the central part of FIG. 4, the data line 107a for G/B and the power supply line 107b for G. Moreover, the subpixel of G at the lower left in FIG. 4 is driven by using the TFT part 108a (M1 switch TFT) and the TFT part 108b (M2 drive TFT) connecting to the gate electrode 105a at the lower side of FIG. 4, the data line 107a for R/G and the power supply line 107b of G. That is, the symmetrical layout of the components in the subpixel of G at the upper right in FIG. 4 and the subpixel of G at the lower left in FIG. 4 with respect to the Y axis allows one data line 107a and one power supply line 107b for G to drive the subpixels. Furthermore, the anode electrode 111 for G and the G light-emitting region 118 are formed in sizes capable of maintaining a distance from the light-emitting region as well as the anode electrodes 111 for R and B. Here, the subpixel of G at the upper right and the subpixel of G at the lower left are so formed that the light-emitting regions of G have substantially the same area and that the center positions of the areas for both subpixels of G are not changed. Furthermore, as needed, four corners are removed from the G light-emitting region 118 in order to secure the distance between apertures of FMM and to facilitate the manufacturing of FMM.

It is to be noted that the color having the highest luminosity factor and the color having the lowest luminosity factor as described in the present specification and claims have relative meanings, indicating “highest” and “lowest” in a comparison among multiple subpixels included in one pixel. Furthermore, the M1 switch TFT 108a is formed to have a dual gate structure as illustrated so as to suppress crosstalk from the data line 107a, and the M2 drive TFT 108b which converts voltage into current is formed to have a routed shape as illustrated in order to minimize the variation in the manufacturing process, thereby ensuring a sufficient channel length. Furthermore, the gate electrode of the drive TFT is extended to be used as an electrode of the retention capacitance part 109 so as to ensure sufficient retention capacitance with a limited area. Such a pixel structure allows the colors of RGB to have larger light-emitting regions, making it possible to lower the current density per unit area of each color for obtaining necessary luminance, and to extend the lifetime of a light emitting element.

While FIG. 5 illustrates a top emission structure in which light radiated from the light emitting element 116 is directed to the outside through the sealing glass substrate 200, a bottom emission structure may also be possible in which the light is radiated to the outside through the glass substrate 101.

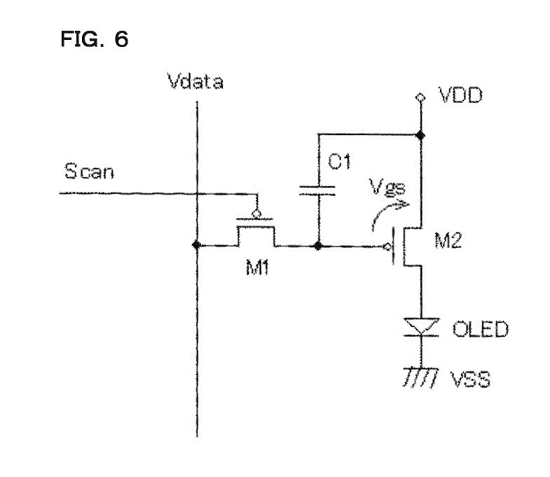

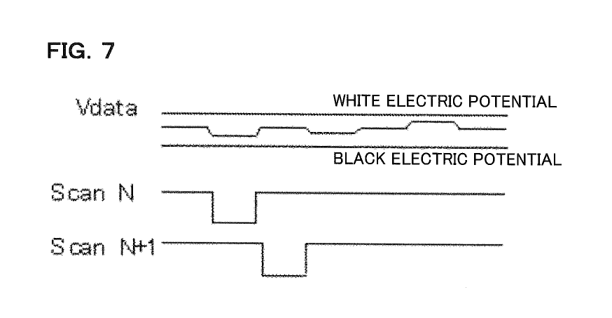

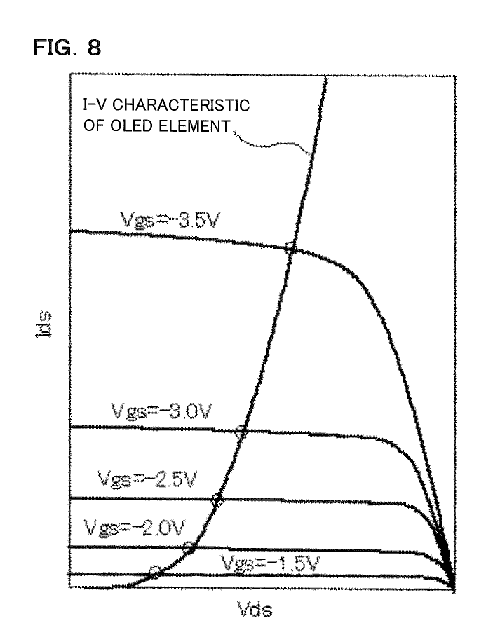

Next, a method of driving each subpixel will be described with reference to FIGS. 6 to 10. FIG. 6 is a main circuit configuration diagram of a subpixel, FIG. 7 is a waveform and FIG. 8 illustrates an output characteristic of a drive TFT. Each subpixel is configured by including the M1 switch TFT, M2 drive TFT, C1 retention capacitance and light emitting element (OLED), and is drive-controlled with a two-transistor system. The M1 switch TFT is a p-channel field effect transistor (FET), the gate terminal of which is connected to a scanning line (Scan) and the drain terminal of which is connected to a data line (Vdata). The M2 drive TFT is a p-channel FET, the gate terminal of which is connected to the source terminal of the M1 switch TFT. Moreover, the source terminal of the M2 drive TFT is connected to the power supply line (VDD), whereas the drain terminal thereof is connected to the light emitting element (OLED). Furthermore, a C1 retention capacitance is formed between the gate and the source of the M2 drive TFT.

In the configuration described above, when a selection pulse is outputted to the scanning line (Scan) to make the M1 switch TFT in an open state, the data signal supplied through the data line (Vdata) is written into the C1 retention capacitance as a voltage value. The retention voltage written into the C1 retention capacitance is held over a period of one frame, the retention voltage causing the conductance of the M2 drive TFT to change in an analog manner, to supply forward bias current, corresponding to a gradation level of light emission, to the light emitting element (OLED).

As described above, since the light emitting device (OLED) is driven with constant current, the luminance of emitted light may be maintained to be constant despite a possible change in the resistance due to degrading of the light emitting device (OLED), which is thus suitable for a method of driving an organic EL display device according to the present embodiment.

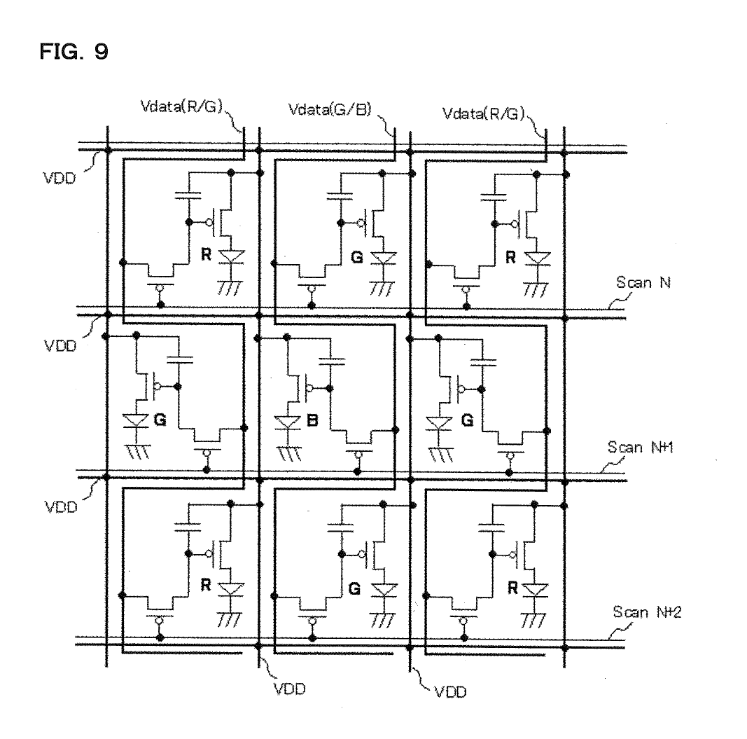

Here, as the subpixels of G are arranged in diagonal directions in the staggered arrangement structure according to the present embodiment, routings of wirings are required. It is preferable here that the power supply line is as straight as possible in order to lower the resistance. Thus, in the present embodiment, the components of a subpixel in an odd-numbered row and a subpixel in an even-numbered row are arranged in a symmetrical layout and the power supply line may be arranged in a straight line, while the data lines are bent. The area of the light-emitting region of a subpixel is made smaller as the number of data lines is increased. Therefore, a data line for a combination of two colors, i.e. G/B or R/G, is repeatedly arranged instead of independently assigning a data line for each color of RGB. The designated pixel array from such a viewpoint leads to the arrangement diagram of wirings and elements as illustrated in FIG. 9.

In other words, the data line for R/G is so bent as to pass through the left (or right) side in the subpixel of R and to pass through the right (or left) side in the subpixel of G. Moreover, the data line for G/B is so bent as to pass through the left (or right) side in the subpixel of G and to pass through the right (or left) side in the subpixel of B. Meanwhile, the power supply lines are formed in straight lines and arranged in grid, which supply power to the subpixels of respective colors by connecting the power supply lines extending in the column direction and in the row direction at the respective grid points.

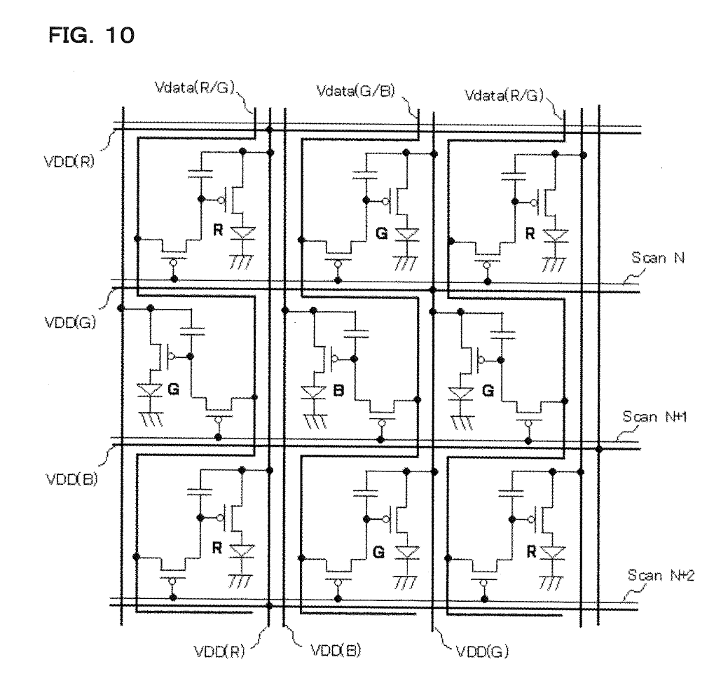

FIG. 9 illustrates a configuration where the power supply lines extending in the column direction and in the row direction are connected at the respective grid points (where the subpixels of different colors share a power supply). In this arrangement structure, the resistance is increased as the path length of the power supply line is longer, which increases the power consumption. Thus, in order to achieve low power consumption, the arrangement structure as illustrated in FIG. 10 may also be possible. More specifically, as in FIG. 9, the components of a subpixel in an odd-numbered row and a subpixel in an even-numbered row are arranged in a symmetrical layout and the power supply line may be arranged in a straight line, while a data line is made for a combination of two colors of G/B or R/G, the data line for the combination of two colors being repeatedly arranged. Furthermore, the mesh structure for the power supply connects the power supply line extending in the column direction and the power supply line extending in the row direction at every three lines.

More specifically, the power supply lines extending in the row direction include the power supply lines of the respective colors of RGB that are repeatedly arranged, while the power supply lines extending in the column direction include a set of the power supply line of R and the power supply line of B as well as the power supply line of G that are repeatedly arranged. The power supply lines in the row direction are connected to the power supply lines in the column direction at every three lines. That is, the same pixel arrangement is repeated at every six rows. By such an arrangement of the wirings and elements, it is possible to increase the areas of the light-emitting regions in subpixels while achieving low power consumption.

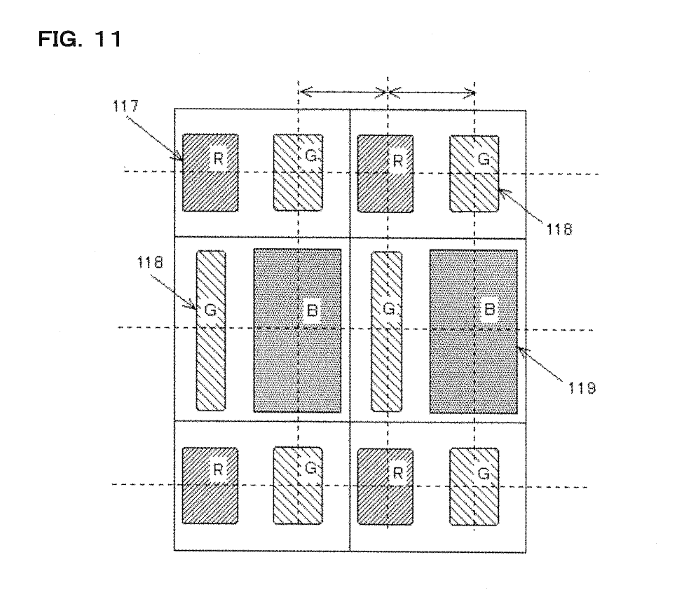

Next, the pixel arrangement structure of an organic EL display device with the structure described above will be described with reference to FIGS. 5 and 11 to 14. The subpixels of RGB illustrated in FIGS. 11 to 14 indicate the light-emitting regions serving as light emitting elements (the portion where the organic EL layer 113 is interposed between the anode electrode 111 and the cathode electrode 114 in FIG. 5). The light-emitting region indicates an aperture of the element separation layer 112. In the case where the organic EL material is selectively deposited using an FMM, an FMM having an aperture slightly larger than the light-emitting region is set in alignment with the TFT substrate and the organic EL material is selectively deposited. Here, electric current actually flows only in portion of the aperture of the element separation layer 112, which will thus be the light-emitting region. If the region of the aperture pattern of FMM overlaps with the region for another color (i.e. if the region where the organic EL material is deposited is widened), a defect called “color shift” occurs in which another luminescent color is mixed. Also, if the region comes inside its own aperture (that is, if the region where the organic EL material is deposited is narrowed), a fault risk of a vertical short-circuiting may be generated in which the cathode electrode 114 and the anode electrode 111 are short-circuited. Accordingly, the aperture pattern of FMM is so designed that an aperture boundary is formed at the outside of the light-emitting region for a target color and located substantially the midway to the light-emitting region for adjacent color. Though the alignment accuracy and the deformation amount of FMM is lower than the manufacturing accuracy in a photo process, the actual light-emitting region is decided by the light-emitting region opened by the photo process, so that any shape may accurately control the area. Moreover, in the case of repeatedly arranging the sets of subpixels, the boundary (solid line) for each pixel in FIGS. 11 to 14 is not defined by the components of the TFT substrate 100 but may be defined based on the relationship between adjacent sets of subpixels. The set of subpixel is defined to form a rectangle here though not necessarily limited to a rectangle.

As illustrated in FIG. 11, the basic structure of the pixel arrangement according to the present embodiment is a pixel arrangement structure in which a row including the subpixels of G and the subpixels of R are alternately arranged (R/G row) and a row including the subpixels of G and subpixels of B are alternately arranged (G/B row) are alternately arranged, and a column including the subpixels of G and subpixels of R are alternately arranged (R/G column) and a column including the subpixels of G and the subpixels of B are alternately arranged (G/B column) are alternately arranged. The height of the G/B row (the light-emitting region of the subpixel of G/B) is higher than the R/G row, while the light-emitting region of the subpixel of G in the G/B row has an area substantially equal to the area of the light-emitting region of the subpixel of G in the R/G row.

In other words, by making the G/B row higher than the R/G row and increasing the area of the subpixel of B having the shortest lifetime, an organic EL display device may have a longer lifetime. Moreover, by narrowing the width of the subpixel of G in the G/B row than the light-emitting region of the subpixel of G in the R/G row, the light-emitting region of the subpixel of G in the G/B row may have an area substantially equal to the area of the light-emitting region of the subpixel of G in the R/G row, which suppresses the occurrence of coloring due to bias in the luminosity factor. Furthermore, by increasing the area of the light-emitting region of the subpixel of B in the G/B row larger than the sum of the areas of the light-emitting regions of the subpixels of G in the G/B row and R/G row, the color of B having the lowest luminosity factor may appropriately be expressed.

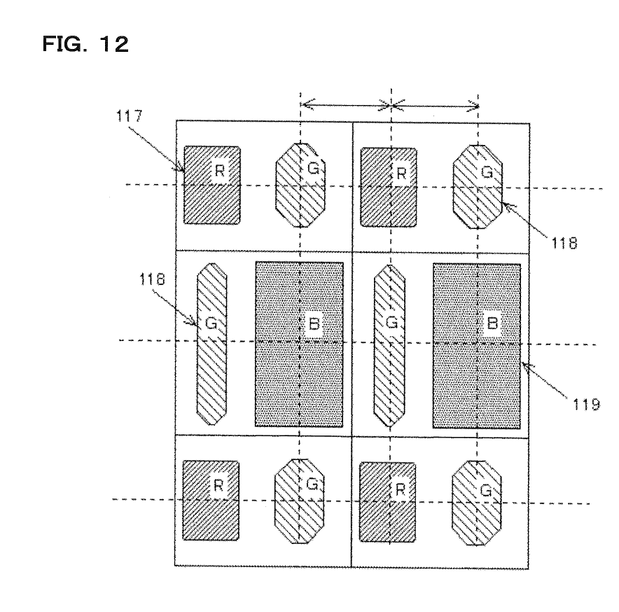

The shape and arrangement of the subpixels of RGB in FIG. 11 is one of examples, and may appropriately be modified. For example, while the light-emitting regions of the subpixels of RGB are formed in rectangular shapes in FIG. 11, an arrangement of the subpixel of G in the R/G row and G/B row narrows the space between G light-emitting regions 118 adjacent to each other in the diagonal directions. The arrangement makes it difficult to divide the color regions of the organic EL materials using FMM. In such a case, as illustrated in FIG. 12, the four corners of the G light-emitting region 118 may be removed so as to secure a space between the G light-emitting regions 118.

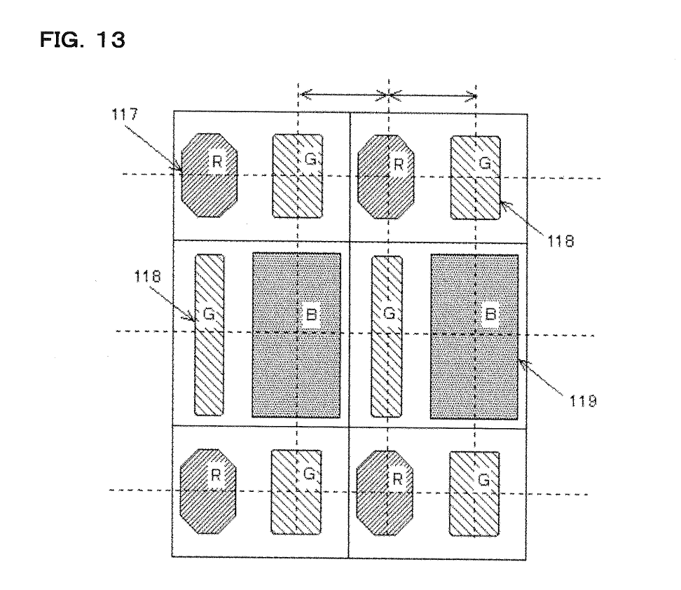

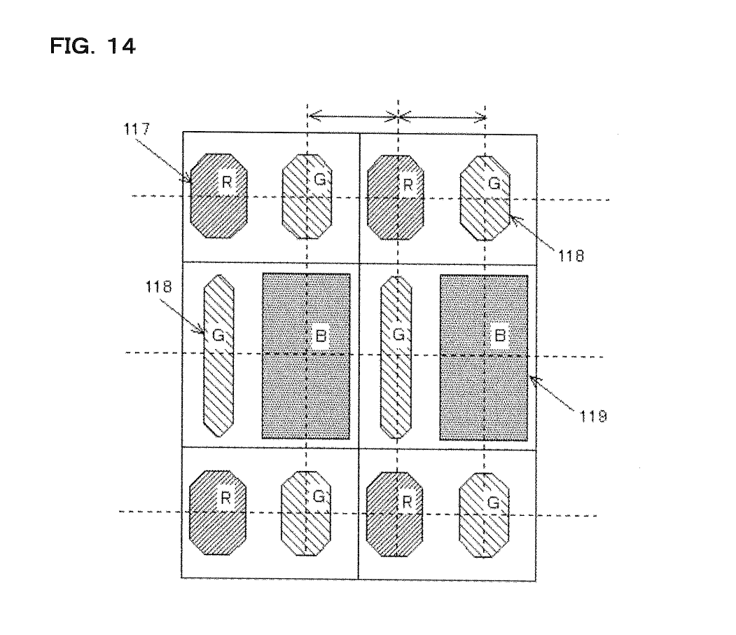

Furthermore, by making the B light-emitting region 119 larger, the distance to the R light-emitting region 117 adjacent in the diagonal directions is narrowed, making it difficult to color-divide the organic EL materials using FMM. In such a case, as illustrated in FIG. 13, the four corners of the R light-emitting region 117 may be removed so as to secure the space between the B light-emitting region 119 and the R light-emitting region 117. Moreover, as illustrated in FIG. 14, the four corners of both the G light-emitting region 118 and the R light-emitting region 117 may be removed. FIG. 4 illustrates the arrangement structure of this case.

It is to be noted that the shape of each subpixel, the space between subpixels, the space between a subpixel and the periphery of the pixel in the pixel arrangement structure are not limited to the illustrated configuration, but may appropriately be modified in consideration of the manufacturing accuracy and the display performance required for an organic EL display device. For example, though each light-emitting region of RGB is formed in a rectangle or an octangle in FIGS. 11 to 14, each subpixel may have a shape of a circle or an ellipse, a vertically or horizontally asymmetric shape, a point symmetric shape or the like as long as the subpixel of B has a large area while the areas of subpixels of G along a diagonal line are substantially equal.

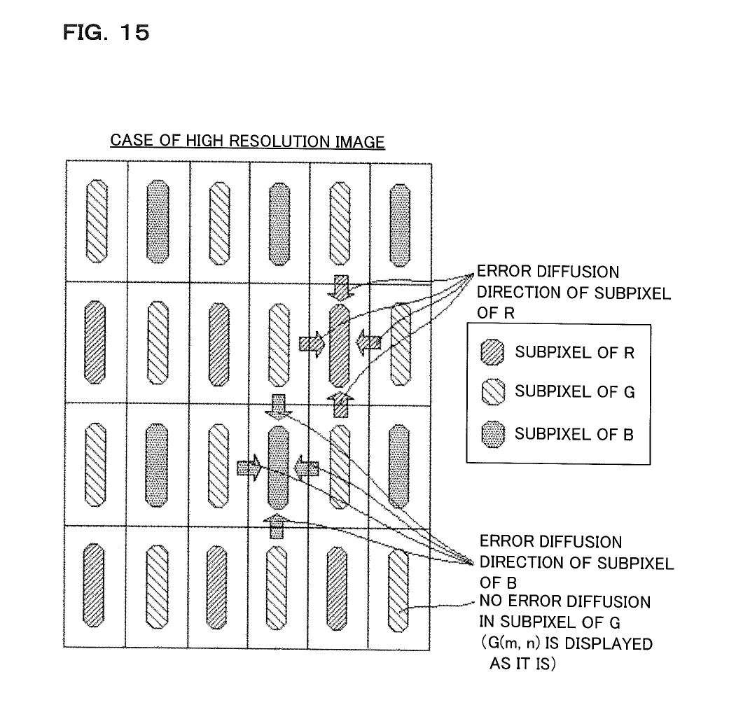

Next, a pixel rendering method for the pixel arrangement structure above will be described with reference to FIGS. 15 to 23. It is to be noted that, in FIGS. 15 to 21 and 23, the subpixels of the colors of RGB are formed in the same shape, the same row height and column width in order to clarify the performance of the error diffusion processing. Moreover, in FIGS. 15 to 21, a clarification case is assumed where original data of RGB is present for each subpixel (where the pixel data is constituted by the number of subpixels×original data of RGB).

FIG. 15 is an example of rendering method suitable for the case where a high resolution image such as a natural painting is displayed. In the staggered arrangement structure for G according to the present embodiment, the number of the subpixels of R or B is only half of the subpixels of G. Thus, as for the subpixels of R and B, in order to ensure the average color balance, same color data in the subpixels of G on the upper, lower, right and left sides are adjusted by error diffusion processing and then, an image is displayed. That is, the luminance of a subpixel of R (or B) is set to a value obtained by adding the original data of R (or B) in the subpixels of G on the upper, lower, right and left sides to the original data of R (or B) in the subpixel of interest, thereby increasing the luminance of the subpixel of R (or B).

For example, where the original data of the subpixels of respective colors in m rows and n columns is indicated as R (m, n), G (m, n) and B (m, n), and the luminance after error diffusion processing of the subpixel of R is indicated as R′ (m, n),

$${R}^{′} ( m , n ) = K \times R ( m , n ) + ( 1 - K ) \text{/} 4 \times ( R ( m - 1 , n ) + R ( m , n - 1 ) + R ( m , n + 1 ) + R ( m + 1 , n ) ) , wherein 0.5 \leq K \leq 1.$$

Likewise, if the luminance after error diffusion processing of the subpixels of B in m rows and n columns is indicated as B′ (m, n),

$${B}^{′} ( m , n ) = L \times B ( m , n ) + ( 1 - L ) \text{/} 4 \times ( B ( m - 1 , n ) + B ( m , n - 1 ) + B ( m , n + 1 ) + B ( m + 1 , n ) ) , wherein 0.5 \leq L \leq 1.$$

As for the subpixel of G, no error diffusion processing is performed in order to secure the resolution, and the luminance of the original data of G (m, n) is indicated. Thus, by setting the luminance of the subpixels of R and B to a value added by the data of the same color in the subpixels of G in the upper, lower, right and left sides, resolution higher than that in the pixel arrangement structure of PenTile arrangement may be realized.

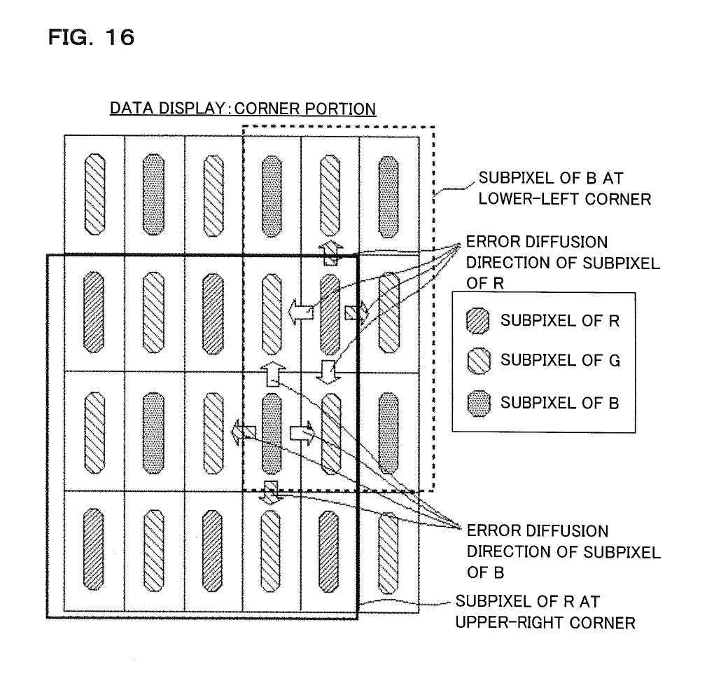

FIG. 16 is an example of rendering method in the case where the corner portion at which the problem of color edge most significantly appears corresponds to the subpixel of R or B (an effective method in data display).

For example, as illustrated in the thick solid line in FIG. 16, in the case where the corner at the upper right in the displayed image is the subpixel of R, the corner is viewed as being colored with R. In such a case, the luminance of the subpixel of G adjacent to the inner side of the displayed image is lowered while the luminance of the subpixel of G adjacent to the outer side of the displayed image is raised (to emit or turn on light), thereby making R unnoticeable. More specifically, the original data of G in the subpixel of R at the corner is set as G (m, n), and the value of K is set to be in the range of, for example, 0 to 0.5, so that error diffusion processing is performed to the subpixel of G on the left and lower sides by −KG (m, n) and to the subpixel of G on the right and upper sides by +KG (m, n).

Similarly, as illustrated in the thick broken line in FIG. 16, in the case where the corner at the lower left in the displayed image is the subpixel of B, the corner is viewed as being colored with B. In such a case also, the luminance of the subpixel of G adjacent to the inner side of the displayed image is lowered while the luminance of the subpixel of G adjacent to the outer side of the displayed image is raised (to emit or turn on light), thereby making B unnoticeable. More specifically, the original data of G in the subpixel of B at the corner is set as G (m, n), and the value of K is set to be in the range of, for example, 0 to 0.5, so that error diffusion processing is performed to the subpixel of G on the right and upper sides by −KG(m, n) and to the subpixel of G on the left and lower sides by +KG(m, n).

In the case where the corner of the displayed image corresponds to the subpixel of G, error diffusion processing is not required. Accordingly, in the case where the corner of the displayed image corresponds to the subpixel of R or B, the luminance of the subpixel of G adjacent to the inner side of the displayed image is lowered while the luminance of the subpixel of G adjacent to the outer side of the displayed image is raised so as to suppress coloring and to enhance the display quality.

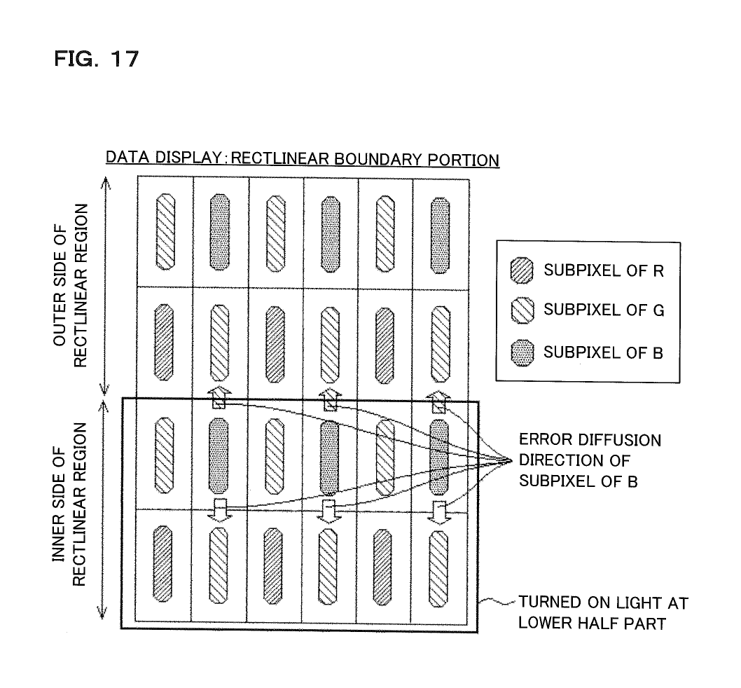

FIG. 17 is an example of rendering method in the case where the rectilinear boundary portion appearing the problem of color edge appears corresponds to the subpixel of R or B. In the case where the subpixel of R or B exists on the rectilinear boundary, the boundary is viewed as being colored with R or B. In such a case, the luminance of the subpixel of G adjacent to the inner side of the rectilinear boundary is lowered while the luminance of the subpixel of G adjacent to the outer side of the rectilinear boundary is raised (to emit or turn on light), thereby making R or B unnoticeable. More specifically, the original data of G in the subpixel of R or B in the boundary portion is set as G(m, n), and the value of L is set to be in the range of, for example, 0 to 0.5, so that error diffusion processing is performed to the subpixel of G at the inner side of the rectilinear boundary by −LG(m, n) and to the subpixel of G at the outer side of the rectilinear boundary by +LG(m, n).

In the case where a subpixel of the rectilinear boundary portion is G, error diffusion processing is not required. Accordingly, in the case where the rectilinear boundary portion corresponds to the subpixel of R or B, the luminance of the subpixel of G adjacent to the inner side of the rectilinear boundary is lowered while the luminance of the subpixel of G adjacent to the outer side of the rectilinear boundary is raised, so as to suppress coloring and to enhance the display quality.

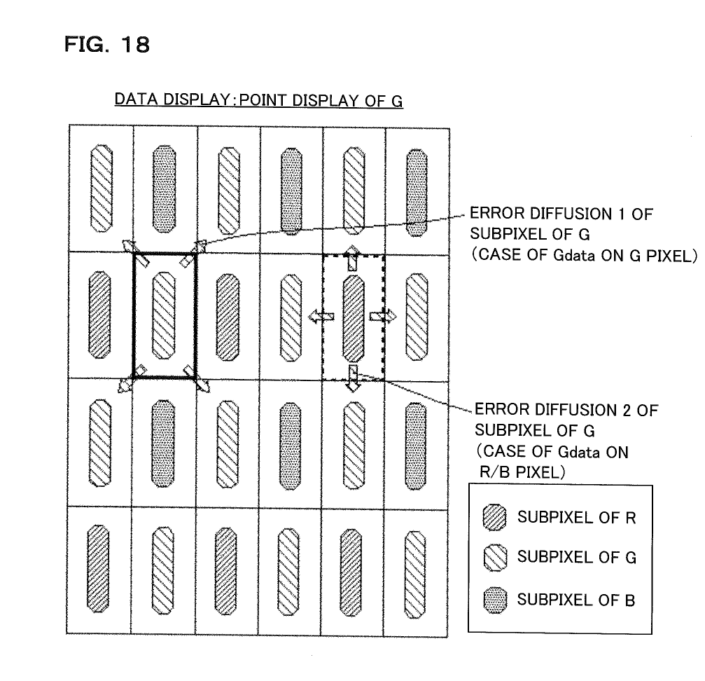

FIG. 18 is an example of rendering method in the case of displaying data for one dot of the subpixel of G. When recognized as data display, even if the display data is data for one dot of subpixel, error diffusion processing is intentionally performed to equalize the display area of dots sensed by the human eye for the case where the data for one dot of subpixel of G is displayed with the subpixel of G and the case where the data is displayed with the subpixel of R or B.

For example, as illustrated in the thick solid line in FIG. 18, in the case where the data for one dot of the subpixel of G is displayed with the subpixel of G (in the case of Gdata on G pixel), the luminance of the subpixel of G is lowered a little and the luminance of the other subpixels of G in the periphery is raised a little (to emit or turn on light). More specifically, the original data of the subpixel of G at the center is set as G(m, n) and the value of L is set to be in the range of, for example, 0 to 0.2, the luminance of four subpixels of G in the periphery is set as L×G(m, n) and the luminance of the subpixel of G at the center is set as (1−L)×G(m, n). It is also possible to change the value of L between the odd-numbered rows and the even-numbered rows (to adjust the values in accordance with the height of the pixel).

Moreover, as illustrated in the thick broken line in FIG. 18, in the case where the data for one dot of the subpixel of G is displayed in the subpixel of R or B (subpixel of R here) (in the case of Gdata on R/B pixel), the luminance of the subpixels of G in the periphery is a little raised (to emit or turn on light). More specifically, when the original data of G in the subpixel of R is set as G (m, n) and J+K=0.5, for example, the luminance of the subpixels of G on the right and left sides is J×G(m, n) and the luminance of the subpixels of G on the upper and lower sides is K×G(m, n). It is possible to change the values of J and K for the odd-numbered rows and the even-numbered rows (to adjust the values in accordance with the height of the pixel).

Accordingly, in the case where the data for one dot of the subpixel of G is displayed, the luminance of the subpixel of G in the periphery is a little raised to equalize the display area of dots sensed by the human eye, thereby enhancing the display quality.

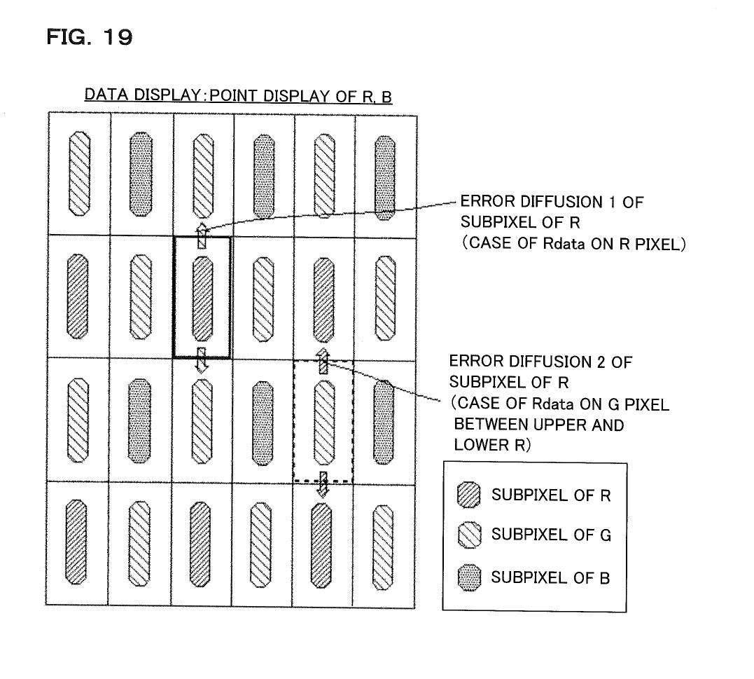

FIG. 19 is an example of rendering method in the case of displaying data for one dot of the subpixel of R or B (R here). When recognized as data display, even if the display data is data for one dot of subpixel, error diffusion processing is intentionally performed to equalize the display area of dots sensed by the human eye for the case where the data for one dot of subpixel of R or B is displayed with the subpixel of R or B and the case where the data is displayed with the subpixel of G.

For example, as illustrated in the thick solid line in FIG. 19, in the case where data for one dot of the subpixel of R is displayed in the subpixel of R (in the case of Rdata on R pixel), the luminance of the subpixel of R is a little lowered while the luminance of the subpixels of G on the upper and lower sides is slightly raised (to emit or turn on light). More specifically, the original data for the subpixel of R is set as R(m, n) and the value of L is set to be in the range of, for example, 0 to 0.1, the luminance of the two subpixels of G on the upper and lower sides is set as L×G(m, n). The luminance of the subpixel of R is then lowered in accordance with the value of L, so that the total luminance is substantially the same as that of the original data. Though it is also possible to perform the error diffusion processing to the subpixels of G on the right and left sides, the diffusion to the subpixels of G on the upper and lower sides, which reduces the difference in recognized areas depending on a location, may be preferable in the case where an odd-numbered row and an even-numbered row have different heights.

Furthermore, as illustrated in the broken line in FIG. 19, where the data for one dot of the subpixel of R is displayed on the subpixel of G (subpixel of G interposed between the subpixels of R on the upper and lower sides) (in the case of the Rdata on G pixel between upper and lower R), the luminance of the subpixel of G is lowered while the luminance of the upper and lower subpixels of R is a little raised (to emit or turn on light). More specifically, the original data of the subpixel of G is set as G(m, n), K is set as approximately 0.5 and the value of L is set to be in the range of 0 to 0.1, the luminance of the subpixels of R on the upper and lower sides is set to be K×G(m, n) while the luminance of the subpixel of G in the middle is set as L×G(m, n), error diffusion processing is performed also to the subpixel of G in the middle. The luminance of the subpixel of R is decreased in accordance with the value of L, so that the total luminance is substantially the same as that of the original data.

Accordingly, in the case where the data for one dot of subpixel of R or B is displayed, the luminance of the subpixels of G on the upper and lower sides of R or B is slightly raised or the luminance of the subpixel of R or B on the upper and lower sides of the subpixel of G is a little raised, so as to equalize the display area for the dots sensed by the human eye and to enhance the display quality.

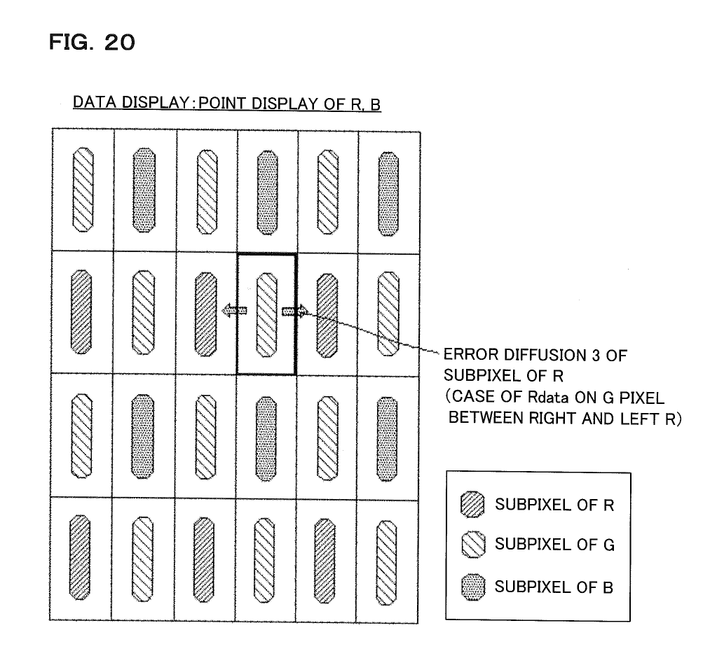

FIG. 20 is another example of rendering method in the case where the data for one dot of subpixel of R or B (R here) is displayed.

For example, as illustrated in the thick solid line in FIG. 20, in the case where data for one dot of the subpixel of R is displayed in the subpixel of G (subpixel of G interposed between the subpixels of R on the right and left sides) (in the case of Rdata on G pixel between right and left R), the luminance of the subpixel of G is lowered while the luminance of the subpixel of R on the right and left sides is a little raised (to emit or turn on light). More specifically, if the original data of the subpixel of G is set as G (m, n), K is set as approximately 0.5 and the value of L is set to be in the range of 0 to 0.1, for example, the luminance of the subpixels of R on the right and left sides is K×G(m, n) while the luminance of the subpixel of G in the middle is L×G(m, n), and error diffusion processing is performed also to the subpixel of G in the middle. The luminance of the subpixel of R is then decreased in accordance with the value of L, so that the total luminance is substantially the same as that in the original data.

Thus, in the case where the data for one dot of the subpixel of R or B is displayed in the subpixel of G, the luminance of the subpixel of G is lowered while the luminance of the subpixel of R or B on the right and left sides of the subpixel of G is a little raised, so as to equalize the display area for the dots sensed by the human eye and to enhance the display quality.

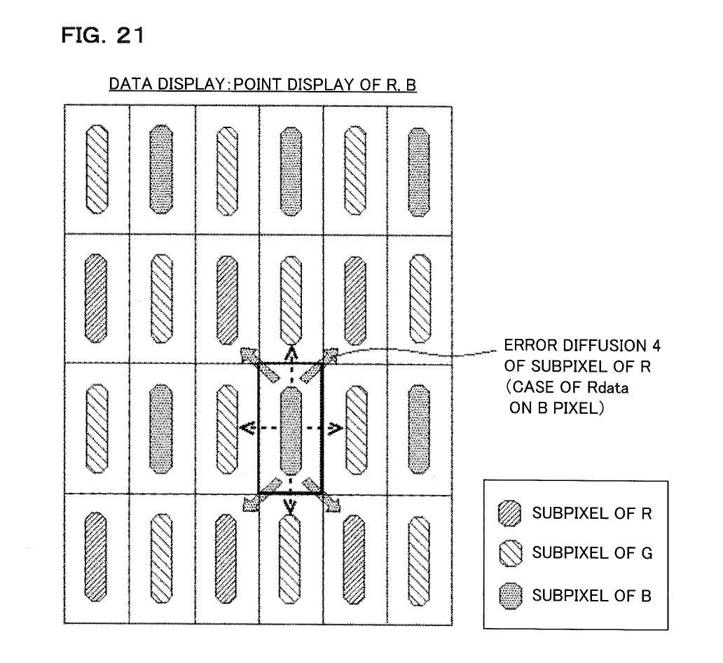

FIG. 21 is another example of rendering in the case where data for one dot of subpixel of R or B (R here) is displayed. This may shift color more or less from the original data, while enhancement in a recognition rate of dots is prioritized in data display.

For example, in the case where data for one dot of subpixel of R is displayed in the subpixel of B as illustrated in the thick solid line in FIG. 21 (in the case of Rdata on B pixel), the luminance of four subpixels of R in the diagonal periphery is a little raised (to emit or turn on light). More specifically, when the original data of the subpixel of R is set as R(m, n) and the value of L is set as approximately 0.25 for example, the luminance of the four subpixels of R in the diagonal periphery is L×R(m, n). Moreover, in order to further enhance the visibility, error diffusion processing may also be performed to the subpixel of G between the subpixels of R (subpixel of G interposed between two subpixels of R in the lateral or vertical direction). In that case, a very small amount (e.g., 5% or less) of error diffusion processing is performed while the luminance of four subpixels of R in the diagonal periphery is lowered accordingly to obtain the total luminance of substantially the same as that of the original data.

As described above, in the case where data for one dot of subpixel of R (or B) is displayed in the subpixel of B (or R), the luminance of four subpixels of R (or B) in the diagonal periphery is a little raised or the luminance of the subpixel of G enclosed by four subpixels of R (or B) in the diagonal periphery is slightly raised, to equalize the display area of dots sensed by the human eye and to enhance the display quality.

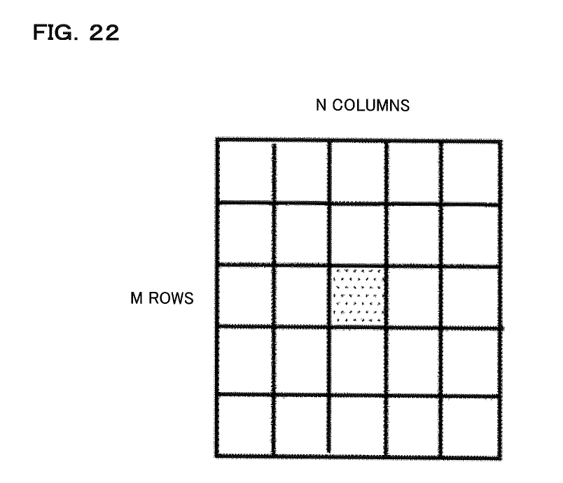

To perform the rendering method as described above, it is necessary to perform error diffusion processing on a displayed image while distinguishing and recognizing which part of the displayed image corresponds to a singularity such as a corner, a boundary or a dot. For example, as illustrated in FIG. 22, in the case where image processing is performed with a matrix of M×N (5×5 here), identification is performed according to a group classification table assuming a 5×5 luminance distribution pattern with respect to the subpixel at the center. As a result, in the case where the subpixel at the center is recognized as a singularity such as a corner, a boundary, a point or the like, data for the subpixel at the center and the subpixels in the periphery thereof is processed based on the error diffusion processing table corresponding to the respective singularities. The processed data is then saved in a line memory for a displayed image. In this method, a line memory corresponding to M×2 rows allows a displayed image to be outputted while sequentially being scanned, which eliminates the need for a separate dedicated frame memory for image processing. That is, the rendering method as described above may be realized with a very small circuitry system.

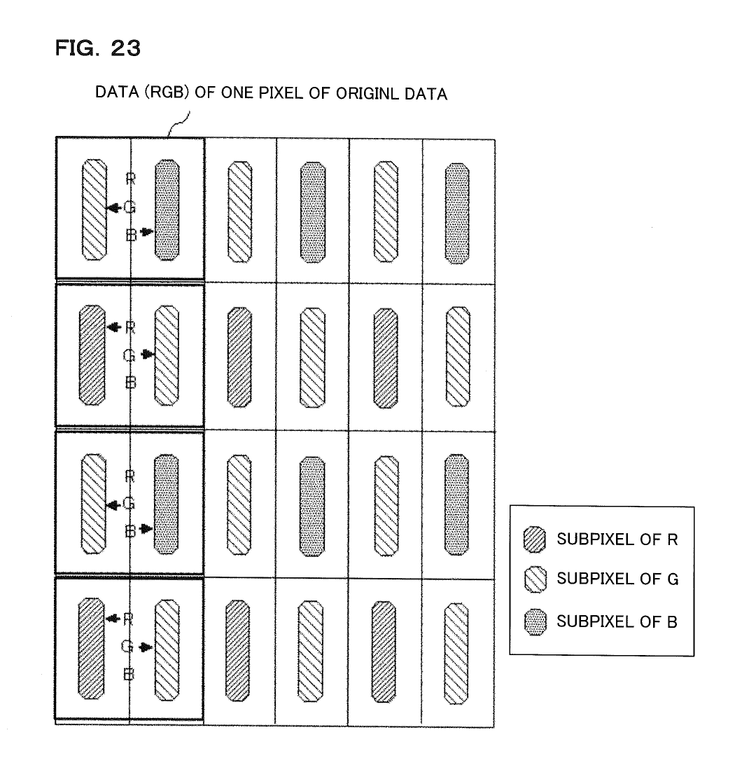

In the case where the original data of RGB corresponding to the number of subpixels exist, error diffusion processing may be performed based on any one of the algorithms described above. When the number of pieces of original data is smaller than the number of subpixels, it is necessary to re-arrange image data. For example, in the case where the number of subpixels is twice the number of pieces of original data and where the resolution is converted at the same ratio as that in the PenTile arrangement, the subpixel of G/B or subpixel of R/G is arranged for one piece of original data, as illustrated in FIG. 23. Though a high resolution image such as natural painting may be displayed as it is, error diffusion processing is performed with a method similar to the algorithm described above in the case of displaying data so as to suppress the effect of color edge. In the case where the number of subpixels cannot be divided by the number of pieces of original data, rearrangement may be performed so that the distribution of luminance signals for original data may be best reflected in the subpixel of G.

### First Example

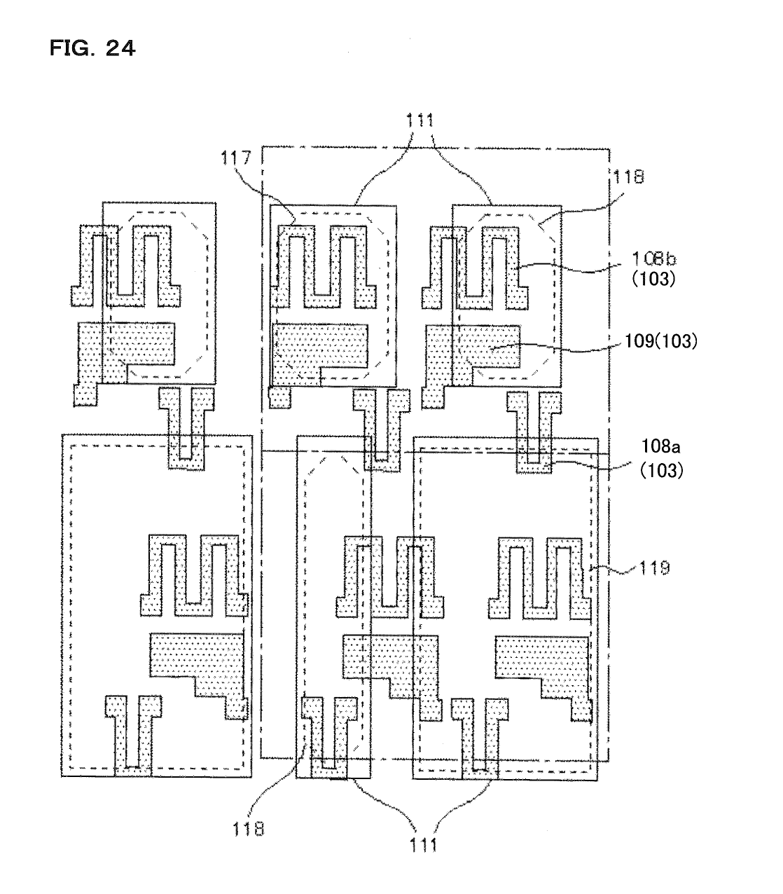

Next, a pixel array and an electro optical device according to the first example will be described with reference to FIG. 24 to FIG. 40.

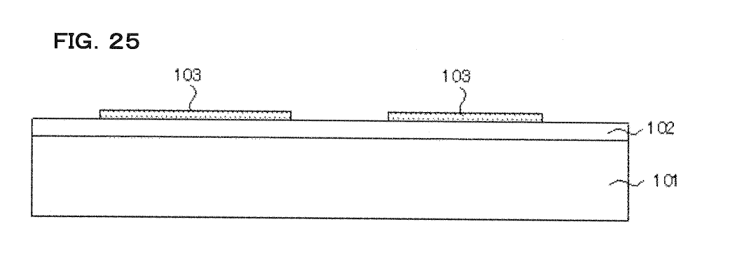

While the pixel arrangement structure in the electro optical device (organic EL display device) has specifically been described in the embodiment as described above, the present example describes a method of manufacturing an organic EL display device including a pixel array having the pixel arrangement structure as described above. FIGS. 24, 26, 28 and 30 are plan views of one pixel with the pixel arrangement structure shown in FIG. 14, whereas FIGS. 25, 27, 29 and 31 are section views of specially extracting a TFT part, a retention capacitance part and a light emitting element illustrated in one subpixel for explanation purpose, corresponding to FIGS. 24, 26, 28 and 30.

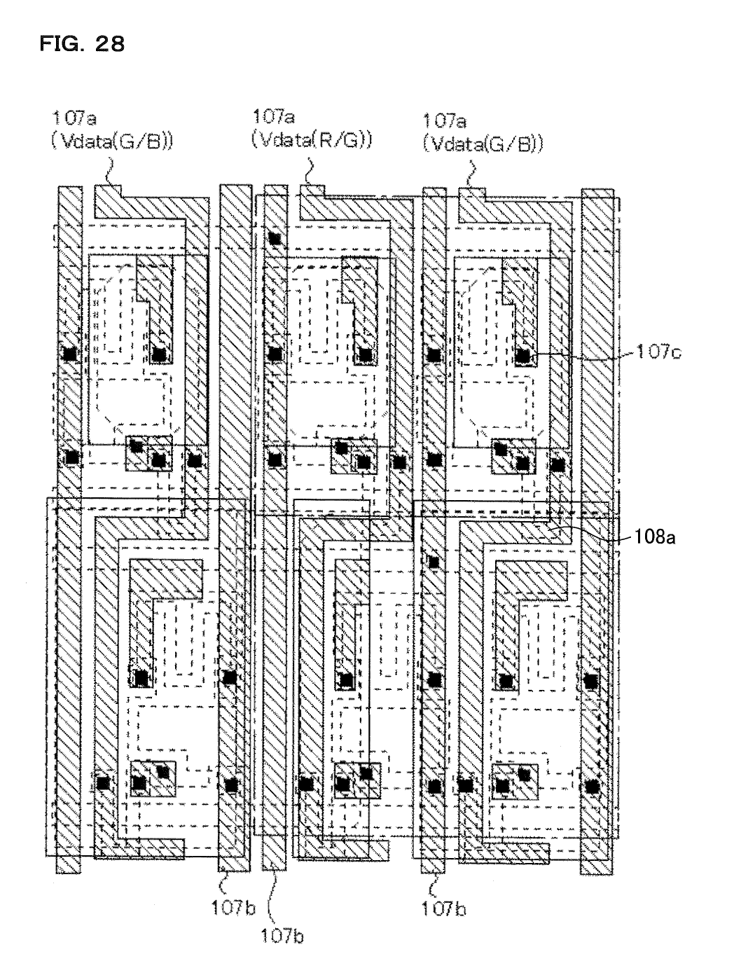

First, as illustrated in FIGS. 24 and 25, an underlying insulation film 102 is formed by depositing, for example, a silicon nitride film using, for example, chemical vapor deposition (CVD) method on a translucent substrate made of glass or the like (glass substrate 101). Next, a TFT part and a retention capacitance part are formed using a known low-temperature poly silicon TFT fabrication technique. More specifically, the CVD method or the like is used to deposit amorphous silicon, which is crystallized by excimer laser annealing (ELA) to form a poly silicon layer 103. In order to ensure positions of the M1 switch TFT 108a, the M2 drive TFT 108b and the C1 retention capacitance 109 in FIG. 24, the boundary of pixels is denoted by dashed-and-dotted lines, the anode electrode 111 is denoted by solid lines, and the R light-emitting region 117, the G light-emitting region 118 and the B light-emitting region 119 are denoted by broken lines. Here, in order to secure a sufficient channel length of the M2 drive TFT 108b which is used as a voltage-to-current conversion amplifier to suppress variation in output current, and to enable the connection between the drain of the M1 switch TFT 108a and the data line 107a (FIG. 28), the connection between the source of the M1 switch TFT 108a and the C1 retention capacitance 109, the connection between the C1 retention capacitance 109 and the power supply line 107b (FIG. 28), the connection between the source of the M2 drive TFT 108b and the power supply line 107b, and the connection between the drain of the M2 drive TFT 108b and the anode electrode 111 of each subpixel, the poly silicon layer 103 is routed as illustrated. In order to obtain a Y-axis symmetrical structure in every row, shapes of the M1 switch TFT, the M2 drive TFT and the C1 retention capacitance at upper side and lower side are changed.

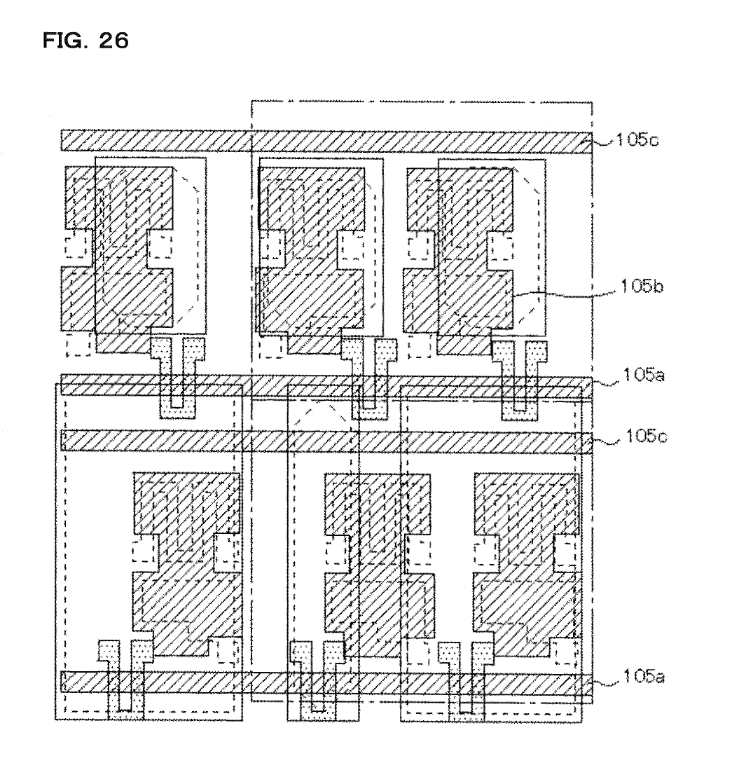

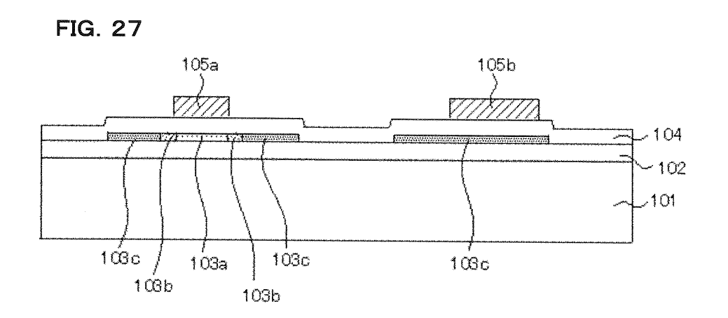

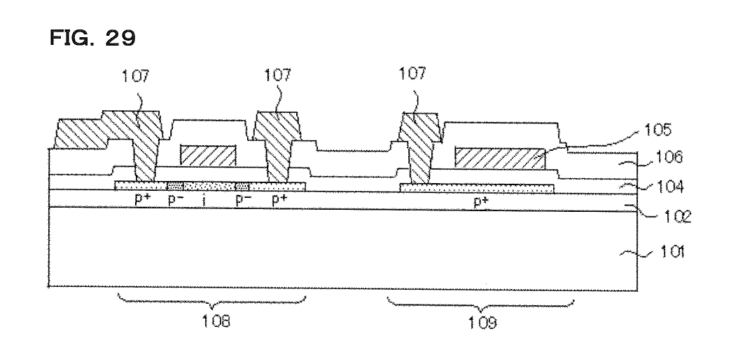

Next, as illustrated in FIGS. 26 and 27, a gate insulation film 104 is formed by depositing, for example, a silicon oxide film using the CVD method or the like on the poly silicon layer 103, and a gate electrode 105a and a retention capacitance electrode 105b are formed by further depositing, for example, molybdenum (Mo), niobium (Nb), tungsten (W) or an alloy thereof as the first metal layer 105 by the spattering technique. In the first example, a power supply line 105c extending in the direction of the gate electrode 105a is formed in the same layer as the gate electrode 105a so as to connect respective power supply lines 107b formed by second metal layers 107 (FIG. 29) described later. It is also possible to form the first metal layer 105 with a single layer of one substance selected from a group including, for example, Mo, W, Nb, MoW, MoNb, Al, Nd, Ti, Cu, Cu alloy, Al alloy, Ag and Ag alloy, or with a layered structure selected from a group including a two or more multi-layered structure of Mo, Cu, Al or Ag which is a low-resistance substance so as to reduce the interconnection resistance. Here, in order to increase the retention capacitance in each subpixel while facilitating the connection between the drain of the M1 switch TFT and the retention capacitance electrode 105b in each subpixel, the first metal layer 105 is formed to have the shape as illustrated. Next, additional impurity doping is applied to the poly silicon layer 103, which had been doped with a heavily-concentrated impurity layer (p+layer 103c) prior to formation of the gate electrode, using the gate electrode 105a as a mask to form a lightly-concentrated impurity layer (p−layer 103b) with an intrinsic layer (i layer 103a) being sandwiched, so as to form a lightly doped drain (LDD) structure in the TFT part.

Next, as illustrated in FIGS. 28 and 29, the CVD method or the like is used to deposit, for example, a silicon oxide film to form an interlayer insulation film 106. Anisotropic etching is performed on the interlayer insulation film 106 and the gate insulation film 104, to open a contact hole for connection to the poly silicon layer 103 and a contact hole for connection to the power supply line 105c. Next, using the spattering technique, the second metal layer 107 made of, for example, aluminum alloy such as Ti/Al/Ti is deposited, and patterning is performed to form the source/drain electrode, the data line 107a, the power supply line 107b, and the first contact part 107c (rectangle part colored in black). Here, the power supply line 107b is formed into a straight-line shape and connected to a predetermined power supply line 105c through the first contact part 107c. The width of the power supply line for B 107b is widened more than the widths of the power supply lines for R and G 107b. The data line 107a has a routed shape so that it is arranged at right side or left side of subpixel in every row. This allows connection between the data line 107a and the drain of the M1 switch TFT 108a, between the source of the M1 switch TFT 108a and the retention capacitance electrode 105b as well as the gate of the M2 drive TFT 108b, and between the sources of the M2 drive TFT 108b and the power supply line 107b.

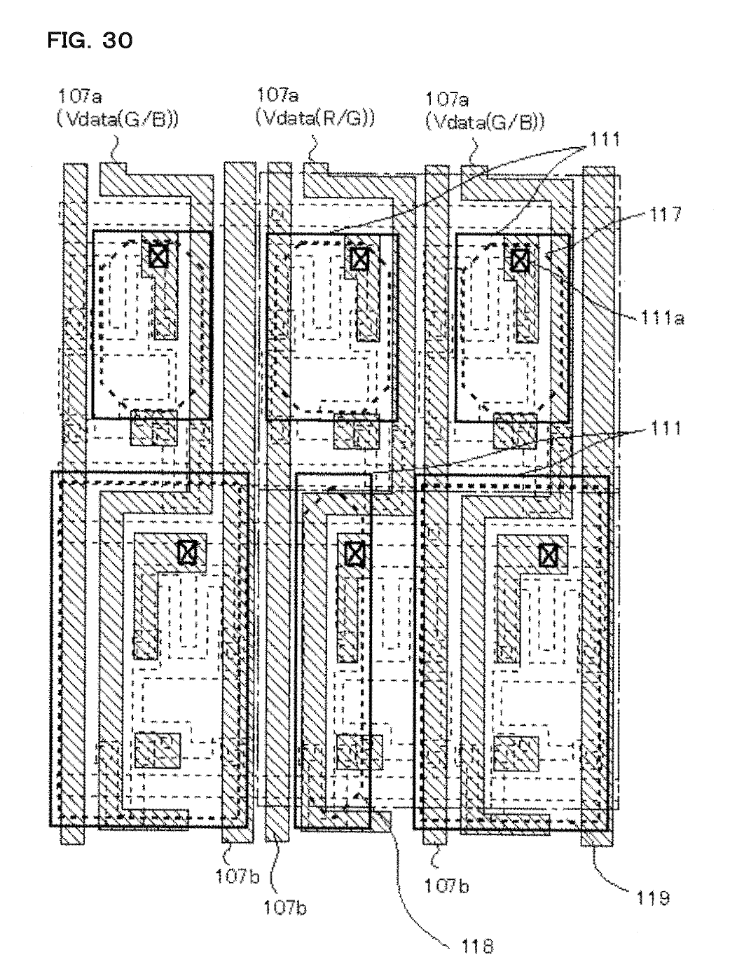

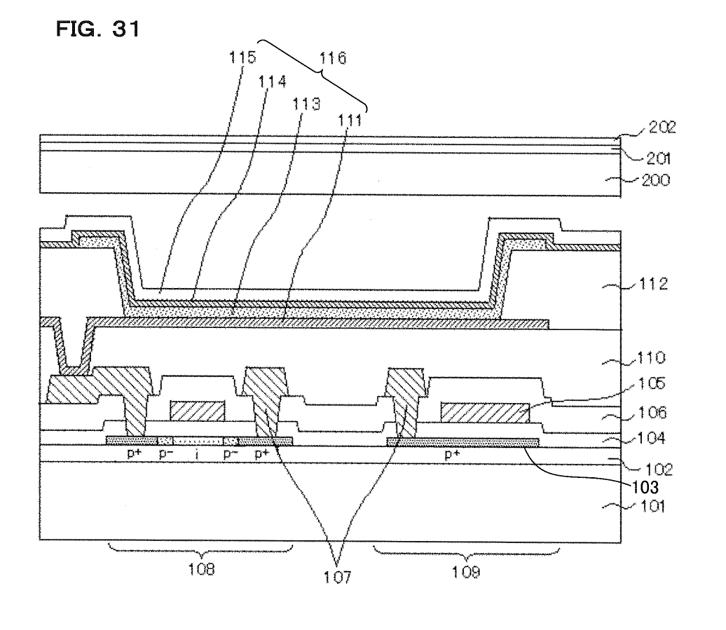

Next, as illustrated in FIGS. 30 and 31, a photosensitive organic material is deposited to form a planarization film 110. The exposing condition is optimized to adjust a taper angle, to open a contact hole (part enclosed by a thick solid line marked with x) for connection to the drain of the M2 drive TFT 108b. A reflection film is deposited thereon with metal of Ag, Mg, Al, Pt, Pd, Au, Ni, Nd, Ir, Cr or a compound thereof, and subsequently a transparent film of ITO, IZO, ZnO, In₂O₃ or the like is deposited thereon, while patterning is performed at the same time to form an anode electrode 111 for each subpixel. The anode electrode 111 is connected to the drain of the M2 drive TFT 108b at the second contact part 111a. Though the anode electrode 111 requires a reflection film since it also serves as a reflection film (not shown) in the top emission structure, the reflection film may be eliminated in the case of a bottom emission structure and the anode electrode 111 may be formed only with a transparent film such as ITO. Next, the spin coating technique is used to deposit, for example, a photosensitive organic resin film to form an element isolation film and then patterning is performed to form an element isolation layer 112 in which the anode electrode 111 of each subpixel is exposed to the bottom. This element isolation layer serves to isolate the light-emitting region of each subpixel.

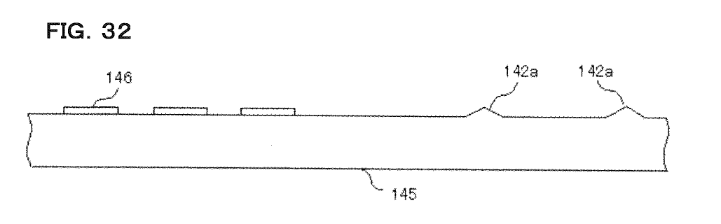

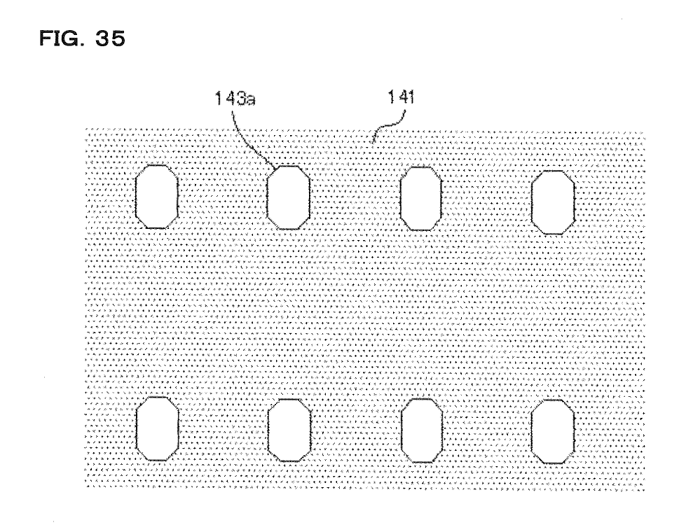

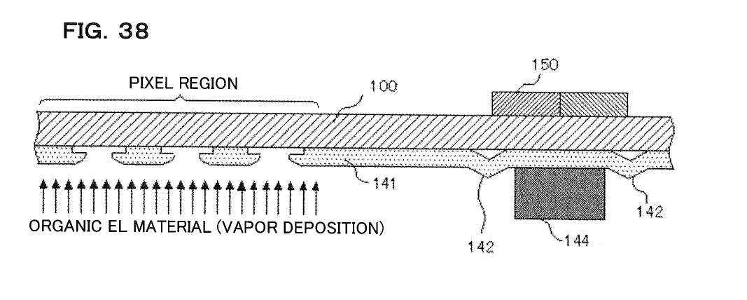

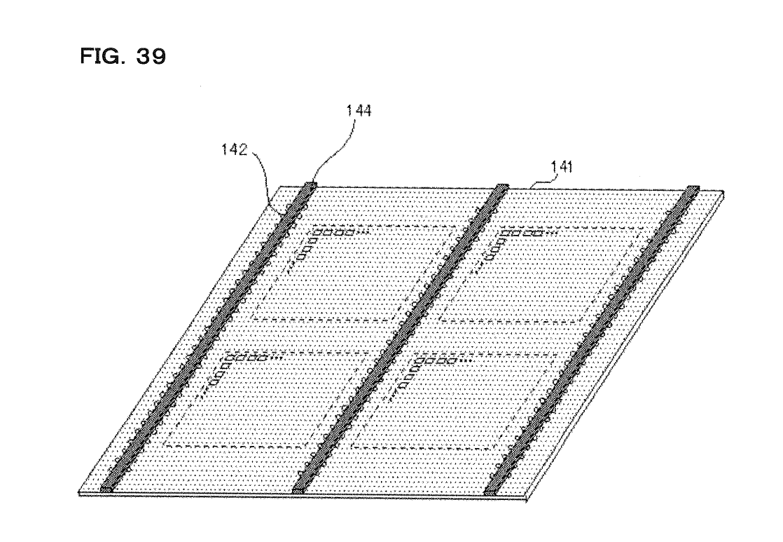

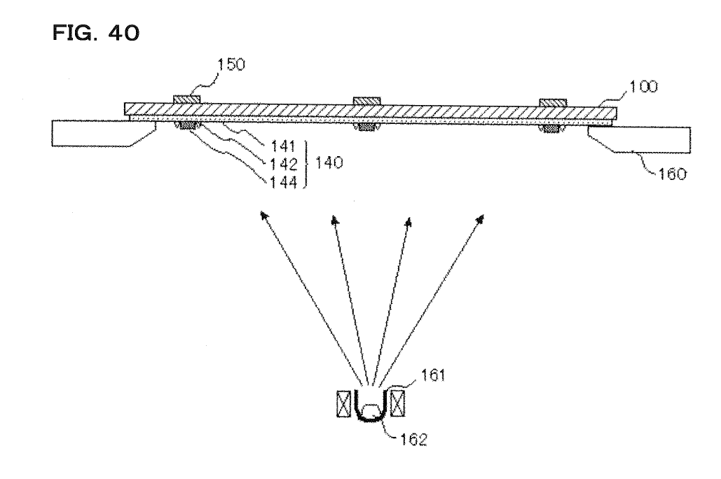

Next, a film of organic EL material is formed on the glass substrate 101 on which the element isolation film 112 is formed. FIGS. 32 to 34 illustrate a method of fabricating a metal mask used in forming the film of organic EL material, showing the region near an end of an organic EL panel. Furthermore, FIGS. 35 to 37 are plan views of a part of a metal mask for forming a film of organic EL material for a different color, FIGS. 38 and 40 are schematically section views of a method of forming a film of organic EL material using the metal mask, and FIG. 39 is a perspective view of the positional relationship between a metal mask main body and its reinforcement member.

First, before forming a film of organic EL material, the method of fabricating a metal mask is described. The metal mask may also be fabricated by forming an aperture at a portion corresponding to a subpixel of a metal mask member having a thin plate shape by punching or etching. In this description, a plating technique is explained as one of the fabricating method. More specifically, as illustrated in FIG. 32, a base material (electrocasting base material 145) for plating growth of the metal mask body is prepared. The material for the electrocasting base material 145 is not specifically limited but may be a material (glass material or alumite, for example) which has sufficient conductivity for flowing the current for electrolytic plating (not required in the case of electroless plating) and which may form concavity and convexity shapes by a technique such as cutting or etching.

Then, a protrusion 142a is formed at a portion where an arranged guide part 142 for the reinforcement member for the metal mask is formed (i.e. a portion outside the pixel region of the organic EL panel), as needed. An underlying layer is formed by deposition of a conductive adhesive or black lead for a metal mask member 141a to easily be exfoliated or by plating growth of a coating film, as needed. Photoresist is deposited to the entire surface of the electrocasting base material 145, and light exposure and developing processes are performed so as to have a photoresist 146 remaining in a portion corresponding to a subpixel in each pixel. In the plating process, since the metal mask member 141a grown from the electrocasting base material 145 grows to cover the photoresist 146, the size of the photoresist pattern is determined in consideration of the amount of the metal mask member 141a covering the photoresist 146 and the thickness of the photoresist 146 and the condition of plating growth are set.

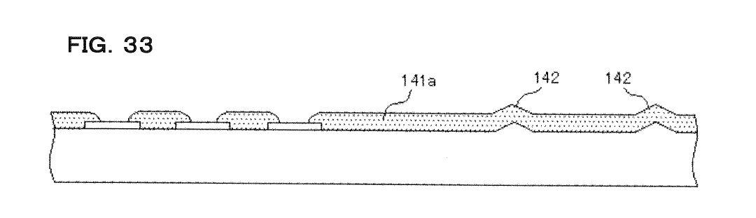

Next, the electrocasting base material 145 with forming the photoresist 146 is soaked in an electrolytic solution, and predetermined current is applied for electrolytic plating, to let the metal mask member 141a having a predetermined thickness grow on the electrocasting base material 145, as illustrated in FIG. 33. A material of metal mask member 141a may be, for example, nickel, nickel alloy, nickel-cobalt alloy, nickel-iron alloy such as invar. It is also possible, in the plating growth of the metal mask member 141a, to use a method of forming the first metal to the thickness corresponding to that of a photoresist and then forming the second metal thereon as disclosed in Japanese Patent Application Laid-Open Publication No. 2005-206881.

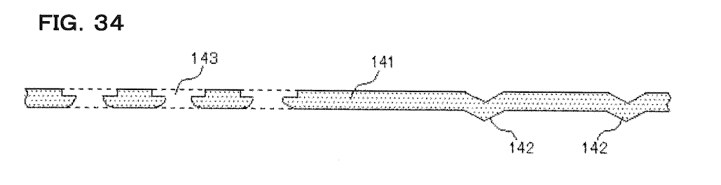

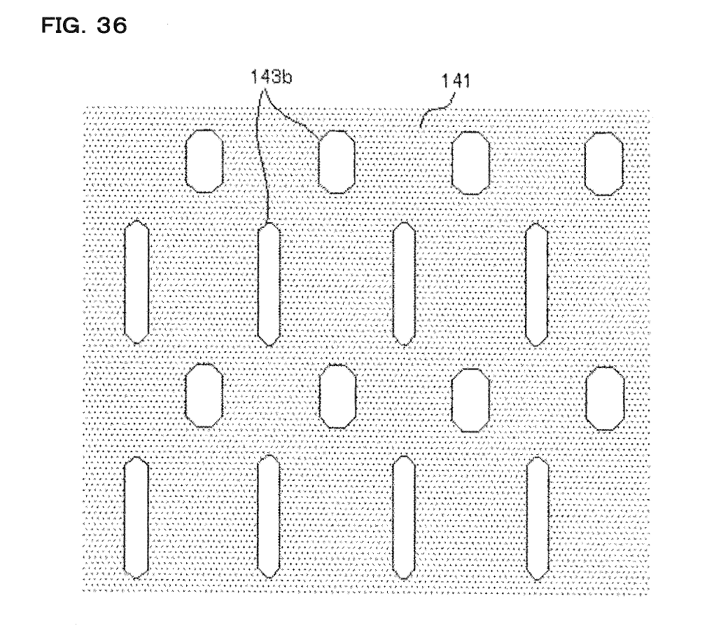

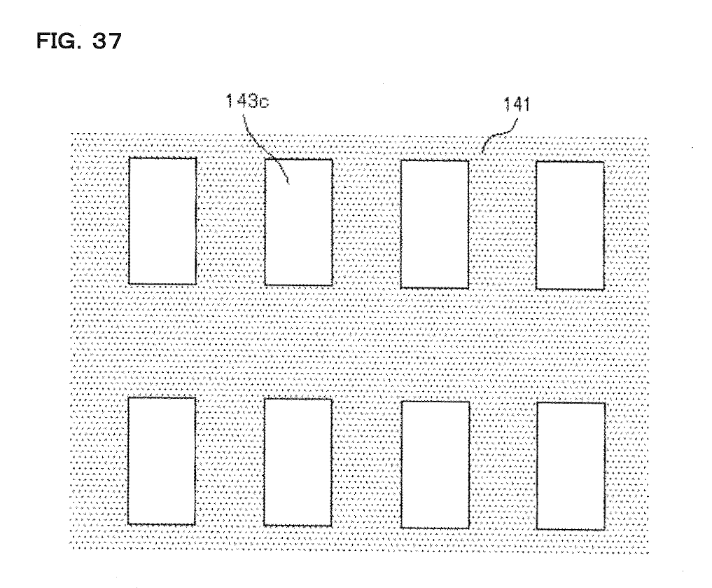

After the plating growth, the electrocasting base material 145 with the grown metal mask member 141a is soaked in a predetermined stripping solution (e.g., acetone or methyl chloride) to separate the metal mask member 141a from together with the photoresist 146 and the electrocasting base material 145, to completely form the metal mask main body 141 in which the aperture 143 and the guide part 142 corresponding to subpixels are formed, as illustrated in FIG. 34. FIG. 35 is an example of the metal mask main body 141 in which an R aperture 143a corresponding to the subpixel of R is formed, FIG. 36 is an example of the metal mask main body 141 in which a G aperture 143b corresponding to the subpixel of G is formed, and FIG. 37 is an example of the metal mask main body 141 in which a B aperture 143c corresponding to the subpixel of B is formed. In the first example, though the subpixels of G exist successively in the diagonal line direction, as illustrated in FIG. 36, four corners of each G aperture 143b are not removed from the metal mask main body 141, making it possible to increase the space between G apertures 143b, thereby facilitating the fabrication of a metal mask.

Thereafter, as illustrated in FIGS. 38 to 40, a reinforcement member 144 having a predetermined characteristic (strength, coefficient of thermal expansion and magnetic property) is arranged at a properly-aligned position on a portion using the guide part 142 of the metal mask main body 141. The metal mask main body 141 provided with the reinforcement member 144 is arranged at a properly-aligned position on the top surface (the film forming surface on which the bank layer described above is formed) of the TFT substrate 100, and a fixing member 150 such as a magnet is arranged at a position opposed to the reinforcement member 144 on the rear surface of the TFT substrate 100, so as to fix the metal mask 140 to the TFT substrate 100. The TFT substrate 100 is then set in a stage 160 in a vacuum chamber of a vapor deposition apparatus with the surface thereof facing downward. A crucible 161 in the chamber is heated to evaporate the organic EL material as an evaporation material 162, and the organic EL material is vapor-deposited at a position corresponding to each subpixel of the TFT substrate 100 through the aperture 143 of the metal mask main body 141. The reinforcement member 144 is arranged at an intermediate part of the adjacent organic EL panel forming region. Since no aperture pattern is arranged here, the reinforcement member 144 would not affect any aperture pattern. Employment of such a structure can suppress deformation of a metal mask, reduce the time and cost for attachment work of the metal mask, and easily restore the misalignment or warpage of the metal mask.

While the guide part 142 is so formed that the surface on the opposite side of the TFT substrate 100 of the metal mask main body 141 protrudes in the description above, it is also possible to form a concave part for guiding so that the surface opposite to the TFT substrate 100 is recessed, which may be fitted with a convex part provided on the reinforcement member 144. Moreover, in the description above, though the cross section of the reinforcement member 144 or fixing member 150 is formed to have a rectangular shape, the cross section is not limited to the illustrated shape but may also be a trapezoidal shape or a semicircular shape. Furthermore, in order for the metal mask main body 141 not to be in contact with the entire surface of the TFT substrate 100, a convex part protruding toward the TFT substrate 100 side may be formed at a predetermined portion outside the organic EL panel forming region such that the metal mask main body 141 makes contact with the TFT substrate 100 only through the convex part. Furthermore, though a plating technique is used as an example of the method of fabricating the metal mask main body 141 in the description above, an etching technique may alternatively be used.

Referring back to FIGS. 30 and 31, a film of organic EL material may be formed for each color of RGB, and the organic EL layer 113 is formed on the anode electrode 111. Here, since four corners of the R aperture 143a are not removed (that is, four corners of organic EL material for R do not protrude), to increase the distance to the organic EL material for B, it is possible to deposit different organic EL materials easily. The organic EL layer 113 is constituted by, for example, a hole injection layer, a hole transportation layer, a light emission layer, an electron transportation layer, an electron injection layer and the like from the lower layer side. Moreover, the organic EL layer 113 may have any structure of the combinations including: electron transportation layer/light emission layer/hole transportation layer; electron transportation layer/light emission layer/hole transportation layer/hole injection layer; and electron injection layer/electron transportation layer/light emission layer/hole transportation layer, or may be a light emission layer alone, or may also be added with an electron blocking layer or the like. The material for the light emission layer is different for each color, while the film thickness of the hole injection layer, the hole transportation layer or the like is individually controlled for each subpixel as needed.

Metal having a small work function, i.e. Li, Ca, LiF/Ca, LiF/Al, Al, Mg or a compound thereof, is vapor-deposited on the organic EL layer 113 to form a cathode electrode 114. The film thickness of the cathode electrode 114 is optimized to increase the light extraction efficiency and to ensure preferable viewing angle dependence. In the case where the cathode electrode 114 has a high resistance thereby losing the uniformity in luminance, an auxiliary electrode layer is added thereon with a substance for forming a transparent electrode such as ITO, IZO, ZnO or In₂O₃. Furthermore, in order to improve the light extraction efficiency, an insulation film having a refractive index higher than that of glass is deposited to form a cap layer 115. The cap layer 115 also serves as a protection layer for the organic EL element.

As described above, the light emitting element 116 corresponding to each subpixel of RGB is formed, and a portion where the anode electrode 111 and the organic EL layer 113 are in contact with each other (the aperture part of the element separation layer 112) will be the R light-emitting region 117, the G light-emitting region 118 or the B light-emitting region 119.

In the case where the light emitting element 116 has a bottom emission structure, the cathode electrode 114 (transparent electrode such as ITO) is formed on the upper layer of the planarization film 110, whereas the anode electrode 111 (reflection electrode) is formed on the organic EL layer 113. Since the bottom emission structure does not require light extraction to the upper surface, a metal film of Al or the like may be formed thick, which can significantly reduce the resistance value of the cathode electrode and thus the bottom emission structure is suitable for a large device. It is, however, not suitable to a highly precise structure due to an extremely small light-emitting region because the TFT element and the wiring part cannot transmit light.

Next, a glass frit coats around the outer circumference of the TFT substrate 100, a sealing glass substrate 200 is mounted thereon, and the glass frit part is heated and melted with laser or the like to tightly seal the TFT substrate 100 and the sealing glass substrate 200. Thereafter, a λ/4 retardation plate 201 and a polarization plate 202 are formed on the light emission side of the sealing glass substrate 200, to complete the organic EL display device.

While FIGS. 24 to 40 illustrate an example of the method of manufacturing an organic EL display device according to the first example, the manufacturing method is not particularly limited thereto if the pixel arrangement structure described in the embodiment may be realized.

### Second Example

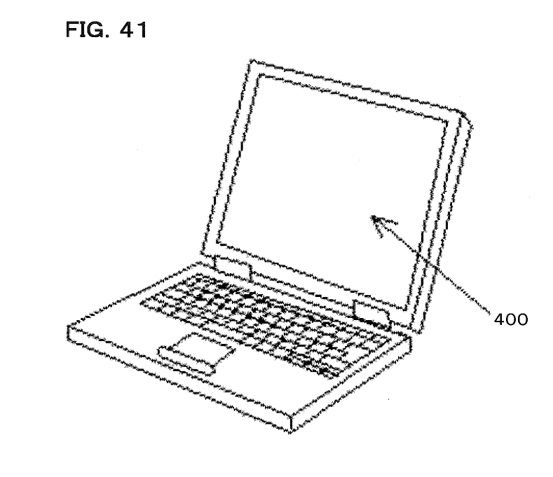

Next, an electro optical device and an electric apparatus according to the second example will be described with reference to FIGS. 41s to 44. In the second example, various types of electric apparatus including an organic EL display device as a display means will be described as an application example of the organic EL display device.

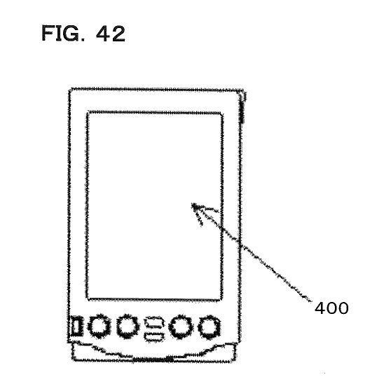

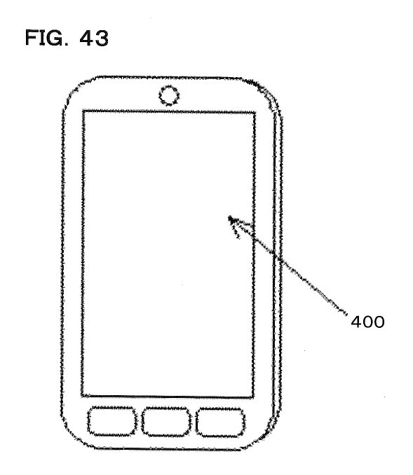

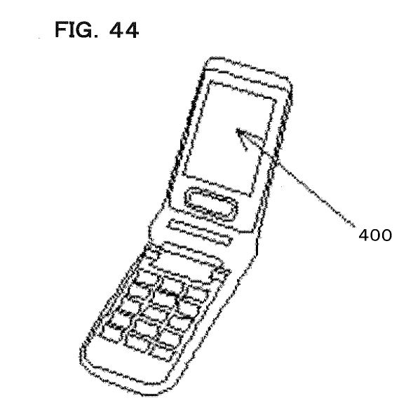

FIGS. 41 to 44 illustrate examples of electric apparatus to which an electro optical device (organic EL display device) is applied. FIG. 41 is an example of application to a personal computer, FIG. 42 is an example of application to a portable terminal device such as a personal digital assistant (PDA), an electronic notebook, an electronic book, a tablet terminal, FIG. 43 is an example of application to a smartphone, and FIG. 44 is an example of application to a mobile phone. The organic EL display device 400 may be utilized for a display part of these types of electric apparatus. Application may be possible to any electric apparatus provided with a display device without specific limitation, for example, to a digital camera, a video camera, a head mounted display, a projector, a facsimile device, a portable TV, a demand side platform (DSP) device and the like.

### Third Example

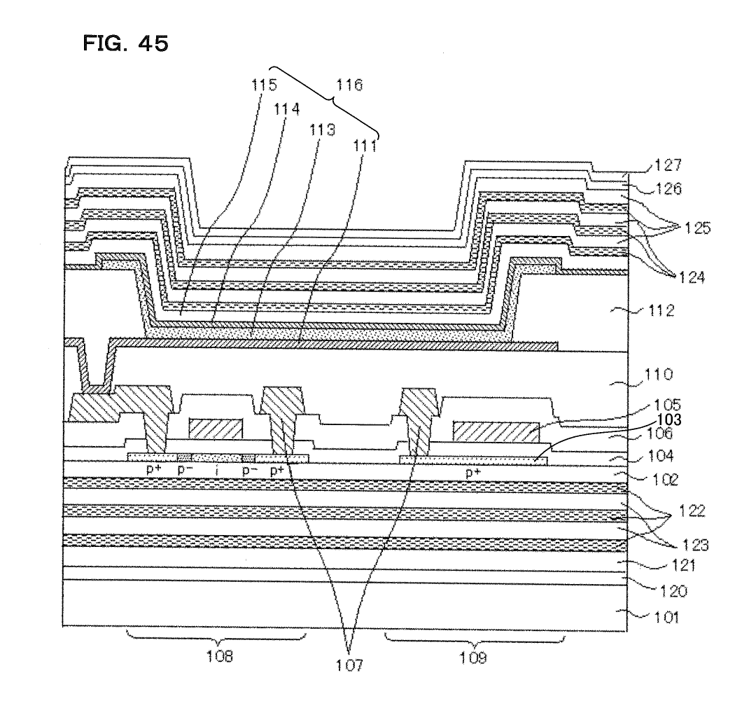

Next, an electro optical device and electric apparatus according to the third example will be described with reference to FIGS. 45 to 48. While a case where the organic EL display device as the electro optical device is applied to electric apparatus provided with a planar display part is described in the second example above, the organic EL display device may also be applied to electric apparatus requiring a curved display part by making it deformable.

FIG. 45 is a section view illustrating a structure of a deformable organic EL display device. This structure is different from the first example described above in that (1) TFT part 108 (M1 switch TFT 108a, M2 drive TFT 108b) and retention capacitance part 109 are formed on a flexible substrate, and (2) no sealing glass substrate 200 is arranged on the light emitting element 116.

First, as to (1), a stripping film 120 such as organic resin which can be removed with a stripping solution is formed on a glass substrate 101, and a flexible substrate 121 having flexibility made of, for example, polyimide is formed thereon. Next, an inorganic thin film 122 such as a silicon oxide film or silicon nitride film and an organic film 123 such as organic resin are alternately layered. Then, on the top layer film (inorganic thin film 122 here), an underlying insulation film 102, a poly silicon layer 103, a gate insulation film 104, a first metal layer 105, an interlayer insulation film 106, a second metal layer 107 and a planarization film 110 are sequentially formed, to form a TFT part 108 and a retention capacitance part 109, according to the manufacturing method described in the first example.

Moreover, as to (2), the anode electrode 111 and the element isolation film 112 are formed on the planarization film 110, and the organic EL layer 113, the cathode electrode 114 and the cap layer 115 are sequentially formed on the bank layer from which the element separation layer 112 is removed, to form the light emitting element 116. Thereafter, an inorganic thin film 124 of a silicon oxide film, silicon nitride film or the like and an organic film 125 of organic resin or the like are alternately layered on the cap layer 115, and a λ/4 retardation plate 126 and a polarization plate 127 are formed on the top layer film (organic film 125 here).

Thereafter, the stripping film 120 on the glass substrate 101 is removed with a stripping solution or the like, to detach the glass substrate 101. In this structure, since the glass substrate 101 and the sealing glass substrate 200 are eliminated while the entire organic EL display device is deformable, application may be possible to electric apparatus having different purposes which requires a curved display part, particularly to wearable electric apparatus.

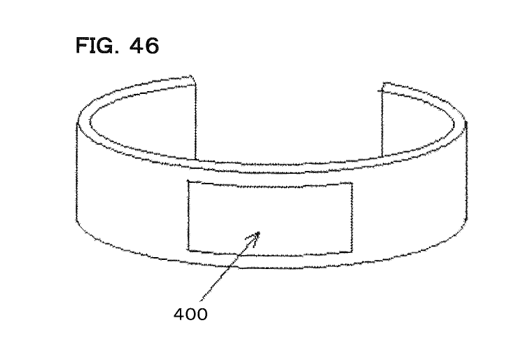

For example, the organic EL display device 400 may be utilized for a display part of wrist band electric apparatus to be attached on a wrist as illustrated in FIG. 46 (terminal linked with a smartphone, terminal provided with a global positioning system (GPS) function, terminal for measuring human body information such as pulse or body temperature, for example). In the case of the terminal linked with a smartphone, a communication means provided in the terminal in advance (short distance wireless communication unit which operates in accordance with a standard such as Bluetooth (registered trademark) or near field communication (NFC)) may be used to display received image data or video data on the organic EL display device 400. Furthermore, in the case of a terminal provided with a GPS function, it is possible to display the positional information, the moving distance information and the moving speed information specified based on GPS signals on the organic EL display device 400. Moreover, in the case of a terminal for measuring human body information, the measured information may be displayed on the organic EL display device 400.

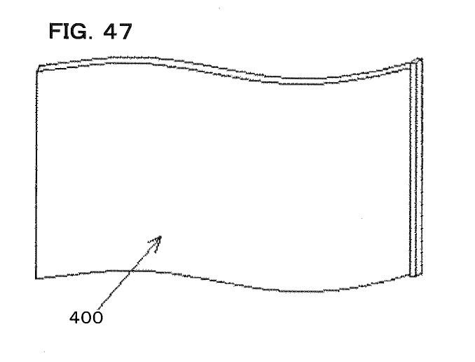

Furthermore, the organic EL display device 400 may also be utilized for an electronic paper as illustrated in FIG. 47. For example, the image data or video data, stored in a storage part located at an end of an electronic paper may be displayed on the organic EL display device 400, or the image data or video data received through an interface means (e.g., a wired communication unit such as universal serial bus (USB) or a wireless communication unit which operates in accordance with a standard such as Ethernet (registered trademark), fiber-distributed data interface (FDDI) or Token Ring located at an end of the electronic paper, may be displayed on the organic EL display device 400.

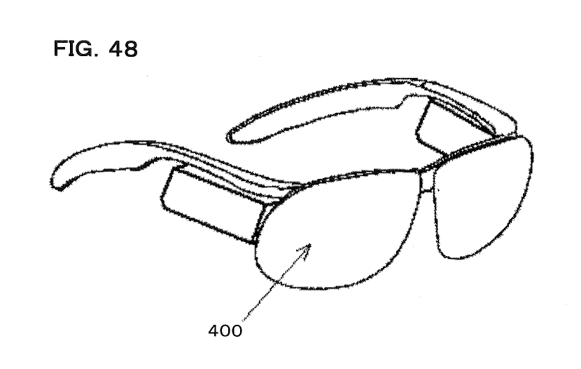

Moreover, the organic EL display device 400 may also be utilized for the display part of a glass-type electronic apparatus to be attached to a face, as illustrated in FIG. 48. For example, the image data or video data stored in a storage part located at a temple of eyeglasses, sunglasses, goggles or the like may be displayed on the organic EL display device 400, or the image data or video data received through an interface means located at the temple (e.g., wire communication unit such as USB, short-distance wireless communication unit which operates in accordance with a standard such as Bluetooth (registered trademark) or NFC, or mobile communication unit for communicating through a mobile communication network such as long term evolution (LTE)/3G), may be displayed on the organic EL device 400.

It is to be understood that the present invention is not limited to the examples described above, but may appropriately be modified for the type or structure of the electro optical device, material of each component, fabrication method and the like without departing from the spirit of the present invention.

For example, though the present embodiments and examples described that the subpixels are three colors of RGB, the above-described pixel arrangement structure may also be applicable to any three colors having different luminosity factors.

While the embodiments and examples illustrated above described that the organic EL material for B has the shortest lifetime, R has the luminance of approximately three times the luminance of B, and thus the organic EL material for R may be degraded faster when compared with the luminance of one third. Here, in the pixel arrangement structure in which the R/G row and the G/B row are alternately arranged and the R/G column and the G/B column are alternately arranged, the height of the R/G row may be made larger than that of the G/B row while the width of the light-emitting region of the subpixel of G in the R/G row may be made narrower than the subpixel of G in the G/B row, so that the area of the light-emitting region of the subpixel of G in the G/B row is substantially equal to the area of the light-emitting region of the subpixel of G in the R/G row. That is, the present invention is to increase the height of the row including the subpixel of a material having the shortest lifetime to be higher than the row not including the subpixel of the material having the shortest lifetime, while changing the width of the light-emitting regions of the subpixels existing in both rows so that light-emitting regions in the subpixels in both rows have substantially the same areas.

Furthermore, the electro optical device is not limited to the organic EL display device as described in the embodiment and examples. Also, the substrate which constitutes pixels is not limited to the TFT substrate as described in the embodiment and examples. The substrate which constitutes pixels may also be applicable to a passive substrate, not limited to an active substrate. Further, though a circuit constituted by an M1 switch TFT, an M2 drive TFT and a C1 retention capacitance (so-called 2T1C circuit) has been illustrated as a circuit to control pixels, a circuit including three or more transistors (e.g., 3T1C circuit) may also be employed.

In a pixel array above described, a pixel arrangement structure in which G/B rows and R/G rows are alternately arranged and G/B columns and R/G columns are alternately arranged (i.e., pixel arrangement structure in which subpixels of G are arranged in a staggered manner) is provided, the height of the G/B row is made larger than that of the R/G row while the width of the light-emitting region in a subpixel of G in the G/B row is made narrower than that in a subpixel of G in the R/G row, so that the areas of the light-emitting regions of the subpixels of G are substantially equal to one another.

By thus increasing the size of the subpixel of B having the shortest lifetime, the lifetime of an electro optical device may be extended. Moreover, the areas of the light-emitting regions for the subpixels of G are made substantially the same in each row, which suppresses the bias in luminosity factors and enhances the display quality of the electro optical device.

Furthermore, the pixel arrangement structure as described above has a layout in which the components of each subpixel in the G/B row and the components of each subpixel in the R/G row are symmetrical with respect to the Y axis (axis extending in the column direction), thereby allowing the power supply line for supplying electric power to two subpixels of G in a pair of pixels to be one straight line, and thus preventing decrease in the area of light-emitting regions due to increase in the number of power supply lines or increase in power consumption due to routing of power supply lines from occurring.

Furthermore, in the case where a singularity such as a corner, a boundary or a point in a displayed image corresponds to a subpixel of a prescribed color, the luminance of the subpixel of another color in the periphery thereof may be adjusted in accordance with a predetermined method of error diffusion processing, to suppress coloring as generated in the PenTile arrangement and to enhance the display quality.

The present invention is applicable to a pixel array having a pixel arrangement structure in which the subpixels of G are arranged in a staggered manner, an electro optical device such as an organic EL display device including the pixel array, an electric apparatus utilizing the electro optical device as a display device, and a pixel rendering method in the pixel arrangement structure.

As this invention may be embodied in several forms without departing from the spirit of essential characteristics thereof, the present embodiment is therefore illustrative and not restrictive, since the scope of the invention is defined by the appended claims rather than by the description preceding them, and all changes that fall within metes and bounds of the claims, or equivalence of such metes and bounds thereof are therefore intended to be embraced by the claims.

What is claimed is:

1. A pixel array, in which a subpixel of a first color having a highest luminosity factor, a subpixel of a second color and a subpixel of a third color having a lowest luminosity factor are arranged in matrix, comprising:
a row including the subpixel of the first color and the subpixel of the second color that are alternately arranged and
a row including the subpixel of the first color and the subpixel of the third color that are alternately arranged are alternately arranged; and
a column including the subpixel of the first color and the subpixel of the second color that are alternately arranged and
a column including the subpixel of the first color and the subpixel of the third color that are alternately arranged are alternately arranged,
wherein the row including the subpixel of the first color and the subpixel of the third color that are alternately arranged is higher than the row including the subpixel of the first color and the subpixel of the second color that are alternately arranged, and
the subpixel of the first color in the row including the subpixel of the first color and the subpixel of the second color that are alternately arranged has an area of a light-emitting region substantially equal to an area of a light-emitting region in the subpixel of the first color in the row including the subpixel of the first color and the subpixel of the third color that are alternately arranged.

2. The pixel array according to claim 1, wherein
the area of the light-emitting region in the subpixel of the third color is larger than a sum of the area of the light-emitting region in the subpixel of the first color in the row including the subpixel of the first color and the subpixel of the second color and the area of the light-emitting region in the subpixel of the first color in the row including the subpixel of the first color and the subpixel of the third color.

3. The pixel array according to claim 1, wherein
a layout of components of subpixels in the row including the subpixel of the first color and the subpixel of the second color is symmetrical with a layout of components of subpixels in the row including the subpixel of the first color and the subpixel of the third color with respect to a line extending in a column direction.

4. The pixel array according to claim 3, wherein
a power supply line supplying electric power to the subpixel of the first color, the subpixel of the second color and the subpixel of the third color has a rectilinear shape, and
a data line supplying a control signal to the subpixel of the first color, the subpixel of the second color and the subpixel of the third color has a bent shape.

5. The pixel array according to claim 4, wherein
the power supply line for the subpixel of the third color is thicker than the power supply line for the subpixel of the first color and the power supply line for the subpixel of the second color.

6. The pixel array according to claim 4, wherein
the control signal is supplied, through a first data line, to the subpixel of the second color in the row including the subpixel of the first color and the subpixel of the second color that are alternately arranged and to the subpixel of the first color in the row including the subpixel of the first color and the subpixel of the third color that are alternately arranged, and
the control signal is supplied, through a second data line, to the subpixel of the first color in the row including the subpixel of the first color and the subpixel of the second color that are alternately arranged and to the subpixel of the third color in the row including the subpixel of the first color and the subpixel of the third color that are alternately arranged.

7. The pixel array according to claim 6, wherein
the first data line and the second data line are bent so as to pass through a left side or a right side of subpixels alternately for each row.

8. The pixel array according to claim 1, wherein
the light-emitting region of the subpixel of the first color has a shape of a rectangle from which four corners are removed.

9. The pixel array according to claim 1, wherein
the light-emitting region of the subpixel of the second color has a shape of a rectangle from which four corners are removed.

10. The pixel array according to claim 1, wherein
the first color is G (Green), the second color is R (Red) and the third color is B (Blue).

11. An electro optical device, comprising:
the pixel array according to claim 1; and
a circuit part driving the pixel array.

12. An electric apparatus, comprising, as a display device, an organic electroluminescence device in which the pixel array according to claim 1 and a circuit part driving the pixel array are formed on a substrate, wherein the pixel array having a light-emitting region of each subpixel defined by an aperture of a metal mask used when organic electroluminescence material is deposited.

13. A pixel rendering method in a pixel array, in which a subpixel of a first color having a highest luminosity factor, a subpixel of a second color and a subpixel of a third color having a lowest luminosity factor are arranged in matrix, a row including the subpixel of the first color and the subpixel of the second color that are alternately arranged and a row including the subpixel of the first color and the subpixel of the third color that are alternately arranged are alternately arranged, and a column including the subpixel of the first color and the subpixel of the second color that are alternately arranged and a column including the subpixel of the first color and the subpixel of the third color that are alternately arranged are alternately arranged, the pixel rendering method comprising:
a step of setting a luminance of a subpixel adjacent to a predetermined subpixel, based on the data of the first color of an image in the predetermined subpixel located at a singularity of the image displayed in the pixel array.

14. The pixel rendering method according to claim 13, wherein
in a case where the subpixel of the second color or the third color is arranged at a corner portion of the image, luminance of two subpixels of the first color adjacent to the subpixel of the second color or the third color within the image is lowered while luminance of two subpixels of the first color adjacent to the subpixel of the second color or the third color outside the image is raised, based on data of the first color of the image in the subpixel of the second color or the third color.

15. The pixel rendering method according to claim 13, wherein
in a case where the subpixel of the second color or the third color is arranged at a boundary portion of a rectilinear region in the image, luminance of the subpixel of the first color adjacent to the subpixel of the second color or the third color in a direction orthogonal to the straight line within the image is lowered while luminance of the subpixel of the first color adjacent to the subpixel of the second color or the third color outside the image is raised, based on data of the first color of the image in the subpixel of the second color or the third color.

16. The pixel rendering method according to claim 13, wherein
in a case where the image is a point of the first color,
in a case where the subpixel of the second color or the third color is located at the point, luminance of four subpixels of the first color adjacent to the subpixel of the second color or the third color is raised, based on data of the first color of the image in the subpixel of the second color or the third color, and
in a case where the subpixel of the first color is located at the point, luminance of the subpixel of the first color is lowered while luminance of four subpixels of the first color adjacent to the subpixel of the first color in diagonal directions is raised, based on data of the first color of the image in the subpixel of the first color.

17. The pixel rendering method according to claim 13, wherein
in a case where the image is a point of the second color or the third color,
in a case where the subpixel of the second color or the third color is located at the point, luminance of the subpixel of the second color or the third color is lowered while luminance of two subpixels of the first color adjacent to the subpixel of the second color or the third color in a row direction or a column direction is raised, based on data of the first color of the image in the subpixel of the second color or the third color, and
in a case where the subpixel of the first color is located at the point, luminance of the subpixel of the first color is lowered while luminance of two subpixels of the second color or the third color adjacent to the subpixel of the first color in a row direction or a column direction is raised, based on data of the first color of the image in the subpixel of the first color.

18. The pixel rendering method according to claim 13, wherein
the first color is G (Green), the second color is R (Red) and the third color is B (Blue).
